(19) United States
(12) Patent Application Publication
(10) Pub. No.: US 2026/0256006 A1
(43) Pub. Date: Aug. 27, 2026

(54) SYSTEMS, METHODS, AND APPARATUS FOR SEMICONDUCTOR PACKAGING WITH EMBEDDED DIES HAVING THERMALLY CONDUCTIVE LAYER

(71) Applicant: Samsung Electronics Co., Ltd., Suwon-si (KR)

(72) Inventors: Yan LI, Morgan Hill, CA (US); WooPoung KIM, San Jose, CA (US)

(21) Appl. No.: 19/357,076

(22) Filed: Oct. 13, 2025

Related U.S. Application Data
(60) Provisional application No. 63/762,621, filed on Feb. 24, 2025.

(51) Int. Cl. H01L 23/00; H01L 21/78; H01L 23/31; H01L 23/498; H01L 23/50; H01L 25/065; H01L 25/16

(52) U.S. Cl. CPC H10W 72/30; H10W 72/00; H10W 74/114; H10W 90/00; H10P 54/00; H10W 70/635; H10W 90/701

(57) ABSTRACT

An apparatus may include a device including a first semiconductor die having a first thermal conductivity, a second semiconductor die having a second thermal conductivity, and a thermally conductive layer having a third thermal conductivity, the thermally conductive layer having a first side connected to the first semiconductor die and a second side connected to the second semiconductor die, wherein the third thermal conductivity may be greater than the first thermal conductivity, and the third thermal conductivity may be greater than the second thermal conductivity. The apparatus may further include a substrate, wherein the device may be at least partially embedded in the substrate. The device may further include a third semiconductor die attached to the first semiconductor die. The device may further include a third semiconductor die attached to the first semiconductor die, and a fourth semiconductor attached to the second semiconductor die.

### REFERENCE TO RELATED APPLICATION

This application claims priority to, and the benefit of, U.S. Provisional Patent Application Ser. No. 63/762,621 filed Feb. 24, 2025 which is incorporated by reference.

### TECHNICAL FIELD

This disclosure relates generally to semiconductor packaging, and more specifically to systems, methods, and apparatus for semiconductor packaging with embedded dies having a thermally conductive layer.

### BACKGROUND

Some semiconductor packaging techniques may combine multiple integrated circuit dies in a package. For example, different types of integrated circuits such as memory devices, processing devices, and/or the like, may be fabricated on separate semiconductor dies using different processes. The dies may be physically and/or electrically connected to one or more substrates and enclosed in a package to provide physical, thermal, and/or electrical protection.

The above information disclosed in this Background section is only for enhancement of understanding of the background of the inventive principles and therefore it may contain information that does not constitute prior art.

### SUMMARY

An apparatus may include a device including a first semiconductor die having a first thermal conductivity, a second semiconductor die having a second thermal conductivity, and a thermally conductive layer having a third thermal conductivity, the thermally conductive layer having a first side connected to the first semiconductor die and a second side connected to the second semiconductor die, wherein the third thermal conductivity may be greater than the first thermal conductivity, and the third thermal conductivity may be greater than the second thermal conductivity. The apparatus may further include a substrate, wherein the device may be at least partially embedded in the substrate. The device may further include a third semiconductor die attached to the first semiconductor die. The device may further include a third semiconductor die attached to the first semiconductor die, and a fourth semiconductor attached to the second semiconductor die. The apparatus may further include a third semiconductor die, and a fourth semiconductor die, wherein the first semiconductor die may be configured to transmit a signal from the third semiconductor die to the fourth semiconductor die. The first semiconductor die may include an integrated circuit. The first semiconductor die may include a memory die. The first semiconductor die may have a first side bonded to the thermally conductive layer, the first semiconductor die may include at least one layer configured as a power delivery network, and the power delivery network may be located adjacent to a second side of the first semiconductor die.

An apparatus may include a substrate, and a device at least partially embedded in the substrate, wherein the device may include a thermally conductive layer having a first thermal conductivity, a first semiconductor die attached to a first side of the thermally conductive layer, the first semiconductor die having a second thermal conductivity, and a second semiconductor die attached to a second side of the thermally conductive layer, the second semiconductor die having a third thermal conductivity, wherein the first thermal conductivity may be greater than the second thermal conductivity, and the first thermal conductivity may be greater than the third thermal conductivity. The first semiconductor die may be bonded to the first side of the thermally conductive layer, and the second semiconductor die may be bonded to the second side of the thermally conductive layer. The apparatus may further include a third semiconductor die attached to a side of the substrate. The apparatus may further include a third semiconductor die attached to a side of the substrate, and a distribution layer attached to the substrate and configured to electrically connect the first semiconductor die to the third semiconductor die. The apparatus may further include a third semiconductor die attached to a side of the substrate, and a fourth semiconductor die attached to the side of the substrate, wherein the first semiconductor die may be configured as a bridge for the third semiconductor die and the fourth semiconductor die. The device may further include a third semiconductor die attached to the first semiconductor die. The device may further include a third semiconductor die attached to the first semiconductor die, and a fourth semiconductor die attached to the second semiconductor die. The substrate may be a first substrate, the device may be a first device, and the apparatus may further include a second substrate connected to the first substrate, the second substrate may include a second device at least partially embedded in the second substrate. The substrate may be a first substrate, the device may be a first device, and the thermally conductive layer may be a first thermally conductive layer, wherein the apparatus may further include a second substrate connected to the first substrate, the second substrate may include a second device at least partially embedded in the second substrate, and the second device may include a second thermally conductive layer having a fourth thermal conductivity, a third semiconductor die having a fifth thermal conductivity attached to a first side of the second thermally conductive layer, and a fourth semiconductor die having a sixth thermal conductivity attached to a second side of the second thermally conductive layer. The fourth thermal conductivity may be greater than the fifth thermal conductivity, and the fourth thermal conductivity may be greater than the sixth thermal conductivity.

A method may include performing, on a semiconductor die, a thinning operation, thereby forming a modified semiconductor die, and bonding, to the modified semiconductor die, a thermally conductive layer, thereby forming a die structure, wherein the thermally conductive layer has a thermal conductivity that may be greater than a thermal conductivity of the semiconductor die. The method may further include embedding, at least partially, the die structure in a substrate. The semiconductor die may be a first semiconductor die and the modified semiconductor die may be bonded to a first side of the thermally conductive layer, the method may further include bonding, to a second side of the thermally conductive layer, a second semiconductor die.

### BRIEF DESCRIPTION OF THE DRAWINGS

The figures are not necessarily drawn to scale and elements of similar structures or functions or portions thereof may generally be represented by reference indicators ending in, and/or containing, the same digits, letters, and/or the like, for illustrative purposes throughout the figures. The figures are only intended to facilitate the description of the various embodiments described herein. The figures do not describe every aspect of the teachings disclosed herein and do not limit the scope of the claims. To prevent the drawings from becoming obscured, not all of the components, connections, and the like, may be shown, and not all of the components may have reference numbers. However, patterns of component configurations may be readily apparent from the drawings. The accompanying drawings, together with the specification, illustrate example embodiments of the present disclosure, and, together with the description, serve to explain the principles of the present disclosure.

FIG. 1 illustrates a first embodiment of a semiconductor die structure in accordance with example embodiments of the disclosure.

FIG. 2 illustrates a second embodiment of a semiconductor die structure in accordance with example embodiments of the disclosure.

FIG. 3A illustrates a cross-sectional view of an embodiment of a semiconductor die having an active layer in accordance with example embodiments of the disclosure.

FIG. 3B illustrates a cross-sectional view of an embodiment of a semiconductor die with semiconductor material removed in accordance with example embodiments of the disclosure.

FIG. 3C illustrates a cross-sectional view of an embodiment of a structure having a thinned semiconductor die attached to a thermally conductive layer in accordance with example embodiments of the disclosure.

FIG. 4 illustrates a cross-sectional view of an embodiment of a substrate including one or more embedded structures having one or more semiconductor dies attached to a thermally conductive layer in accordance with example embodiments of the disclosure.

FIG. 5 illustrates a cross-sectional view of a first example embodiment of a die structure having semiconductor dies bonded to two sides of a thermally conductive layer in accordance with example embodiments of the disclosure.

FIG. 6 illustrates a cross-sectional view of a second example embodiment of a die structure having semiconductor dies bonded to two sides of a thermally conductive layer in accordance with example embodiments of the disclosure.

FIG. 7 illustrates a cross-sectional view of a third example embodiment of a die structure having semiconductor dies bonded to two sides of a thermally conductive layer in accordance with example embodiments of the disclosure.

FIG. 8 illustrates a cross-sectional view of a first example embodiment of a die structure having semiconductor dies bonded to two sides of a thermally conductive layer in accordance with example embodiments of the disclosure.

FIG. 9 illustrates a cross-sectional view of a fourth example embodiment of a die structure having semiconductor dies bonded to two sides of a thermally conductive layer in accordance with example embodiments of the disclosure.

FIG. 10 illustrates a cross-sectional view of a fifth example embodiment of a die structure having semiconductor dies bonded to two sides of a thermally conductive layer in accordance with example embodiments of the disclosure.

FIG. 11 illustrates a cross-sectional view of a first example embodiment of a die structure having two stacked semiconductor dies bonded to a first side of a thermally conductive layer and two stacked semiconductor dies bonded to a second side of the thermally conductive layer in accordance with example embodiments of the disclosure.

FIG. 12 illustrates a cross-sectional view of a second example embodiment of a die structure having two stacked semiconductor dies bonded to a first side of a thermally conductive layer and two stacked semiconductor dies bonded to a second side of the thermally conductive layer in accordance with example embodiments of the disclosure.

FIG. 13 illustrates an enlarged cross-sectional view of a portion of the semiconductor die structure illustrated in FIG. 9 in accordance with example embodiments of the disclosure.

FIG. 14 illustrates an enlarged cross-sectional view of a portion of the semiconductor die structure illustrated in FIG. 11 in accordance with example embodiments of the disclosure.

FIG. 15 illustrates an enlarged cross-sectional view of a portion of the semiconductor die structure illustrated in FIG. 12 in accordance with example embodiments of the disclosure.

FIG. 16A illustrates a plan view of an embodiment of a package architecture including a substrate with an embedded die structure having semiconductor dies attached to two sides of a thermally conductive layer in accordance with example embodiments of the disclosure.

FIG. 16B illustrates a cross-sectional view of the embodiment of the package architecture illustrated in FIG. 16A taken through dot-dashed line A-A in accordance with example embodiments of the disclosure.

FIG. 17A illustrates a plan view of an embodiment of a package architecture including a substrate with an embedded die structure having two stacked semiconductor dies bonded to a first side of a thermally conductive layer and two stacked semiconductor dies bonded to a second side of the thermally conductive layer in accordance with example embodiments of the disclosure.

FIG. 17B illustrates a cross-sectional view of the embodiment of the package architecture illustrated in FIG. 17A taken through dot-dashed line A-A in accordance with example embodiments of the disclosure.

FIG. 18A illustrates a plan view of an embodiment of a package architecture including a substrate with an embedded die structure having two stacked semiconductor dies bonded to a first side of a thermally conductive layer, two stacked semiconductor dies bonded to a second side of the thermally conductive layer, and one or more dies attached to a side of the substrate in accordance with example embodiments of the disclosure.

FIG. 18B illustrates a cross-sectional view of the embodiment of the package architecture illustrated in FIG. 18A taken through dot-dashed line A-A in accordance with example embodiments of the disclosure.

FIG. 19A illustrates a plan view of an embodiment of a package architecture including a substrate with an embedded die structure having two stacked semiconductor dies bonded to a first side of a thermally conductive layer, two stacked semiconductor dies bonded to a second side of the thermally conductive layer, one or more dies attached to a first side of the substrate, and one or more dies attached to a second side of the substrate in accordance with example embodiments of the disclosure.

FIG. 19B illustrates a cross-sectional view of the embodiment of the package architecture illustrated in FIG. 19A taken through dot-dashed line A-A in accordance with example embodiments of the disclosure.

FIG. 20A illustrates a plan view of an embodiment of a package architecture including two or more stacked substrates wherein a substrate may include an embedded die structure having semiconductor dies attached to two sides of a thermally conductive layer in accordance with example embodiments of the disclosure.

FIG. 20B illustrates a cross-sectional view of the embodiment of the package architecture illustrated in FIG. 20A taken through dot-dashed line A-A in accordance with example embodiments of the disclosure.

FIG. 21A illustrates a plan view of an embodiment of a package architecture including two or more stacked substrates and one or more dies and/or die structures attached to a substrate and wherein a substrate may include an embedded die structure having semiconductor dies attached to two sides of a thermally conductive layer in accordance with example embodiments of the disclosure.

FIG. 21B illustrates a cross-sectional view of the embodiment of the package architecture illustrated in FIG. 21A taken through dot-dashed line A-A in accordance with example embodiments of the disclosure.

FIG. 22A illustrates a plan view of an embodiment of a co-packaged optics package architecture including a substrate having an embedded die structure with semiconductor dies attached to two sides of a thermally conductive layer in accordance with example embodiments of the disclosure.

FIG. 22B illustrates a cross-sectional view of the embodiment of the package architecture illustrated in FIG. 22A taken through dot-dashed line A-A in accordance with example embodiments of the disclosure.

FIG. 23A illustrates a plan view of an embodiment of a co-packaged optics package architecture including a substrate having an embedded die structure with semiconductor dies attached to two sides of a thermally conductive layer and a die or die structure attached to a side of the substrate in accordance with example embodiments of the disclosure.

FIG. 23B illustrates a cross-sectional view of the embodiment of the package architecture illustrated in FIG. 23A taken through dot-dashed line A-A in accordance with example embodiments of the disclosure.

FIG. 24A illustrates a plan view of an embodiment of a co-packaged optics package architecture including a substrate having an embedded die structure with semiconductor dies attached to two sides of a thermally conductive layer and a die or die structure attached to a side of the substrate in accordance with example embodiments of the disclosure.

FIG. 24B illustrates a cross-sectional view of the embodiment of the package architecture illustrated in FIG. 24A taken through dot-dashed line A-A in accordance with example embodiments of the disclosure.

FIG. 25A illustrates a cross-sectional view of a first wafer on a first carrier in accordance with example embodiments of the disclosure.

FIG. 25B illustrates a cross-sectional view of a modified first wafer on a first carrier in accordance with example embodiments of the disclosure.

FIG. 25C illustrates a cross-sectional view of thermally conductive layers bonded to a modified first wafer on a first carrier in accordance with example embodiments of the disclosure.

FIG. 25D illustrates a cross-sectional view of thermally conductive layers bonded to singulated portions of a modified first wafer on a first carrier in accordance with example embodiments of the disclosure.

FIG. 25E illustrates a cross-sectional view of die structures including thermally conductive layers bonded to singulated portions of a first modified wafer removed from a first carrier in accordance with example embodiments of the disclosure.

FIG. 25F illustrates a cross-sectional view of die structures including thermally conductive layers bonded to singulated portions of a first modified wafer, wherein the thermally conductive layers are bonded to a second modified wafer on a second carrier in accordance with example embodiments of the disclosure.

FIG. 25G illustrates a cross-sectional view of die structures including thermally conductive layers bonded to singulated portions of a first modified wafer, wherein the thermally conductive layers are bonded to singulated portions of a second modified wafer on a second carrier in accordance with example embodiments of the disclosure.

FIG. 25G illustrates a cross-sectional view of die structures including thermally conductive layers bonded to singulated portions of a first modified wafer, wherein the thermally conductive layers are bonded to singulated portions of a second modified wafer on a second carrier in accordance with example embodiments of the disclosure.

FIG. 25H illustrates a cross-sectional view of die structures including thermally conductive layers bonded to singulated portions of first and second modified wafers removed from a second carrier in accordance with example embodiments of the disclosure.

FIG. 26A illustrates a cross-sectional view of a second wafer on a second carrier in accordance with example embodiments of the disclosure.

FIG. 26B illustrates a cross-sectional view of a modified second wafer on a second carrier in accordance with example embodiments of the disclosure.

FIG. 27A illustrates a cross-sectional view of a substrate core having one or more cavities and/or vias formed therein, in accordance with example embodiments of the disclosure.

FIG. 27B illustrates a cross-sectional view of a substrate core having one or more vias filled with conductive material in accordance with example embodiments of the disclosure.

FIG. 27C illustrates a cross-sectional view of a substrate core attached to a first carrier in accordance with example embodiments of the disclosure.

FIG. 27D illustrates a cross-sectional view of a substrate core having one or more semiconductor dies disposed in one or more cavities therein in accordance with example embodiments of the disclosure.

FIG. 27E illustrates a cross-sectional view of a substrate core having a redistribution layer film and/or build up film laminated thereto in accordance with example embodiments of the disclosure.

FIG. 27F illustrates a cross-sectional view of a substrate core having a second carrier attached thereto in accordance with example embodiments of the disclosure.

FIG. 27G illustrates a cross-sectional view of a substrate core having a second redistribution layer film and/or build up film laminated thereto in accordance with example embodiments of the disclosure.

FIG. 27H illustrates a cross-sectional view of a substrate core having one or more redistribution layers formed thereon in accordance with example embodiments of the disclosure.

FIG. 27I illustrates a cross-sectional view of a substrate core having one or more thermal structures formed thereon in accordance with example embodiments of the disclosure.

FIG. 28A illustrates a cross-sectional view of a substrate core for a co-packaged optics package having one or more cavities and/or vias formed therein, in accordance with example embodiments of the disclosure.

FIG. 28B illustrates a cross-sectional view of a substrate core for a co-packaged optics package having one or more vias filled with conductive material in accordance with example embodiments of the disclosure.

FIG. 28C illustrates a cross-sectional view of a substrate core for a co-packaged optics package attached to a first carrier in accordance with example embodiments of the disclosure.

FIG. 28D illustrates a cross-sectional view of a substrate core for a co-packaged optics package having one or more semiconductor dies disposed in one or more cavities therein in accordance with example embodiments of the disclosure.

FIG. 28E illustrates a cross-sectional view of a substrate core for a co-packaged optics package having a redistribution layer film and/or build up film laminated thereto in accordance with example embodiments of the disclosure.

FIG. 28F illustrates a cross-sectional view of a substrate core for a co-packaged optics package having a second carrier attached thereto in accordance with example embodiments of the disclosure.

FIG. 28G illustrates a cross-sectional view of a substrate core for a co-packaged optics package having a second redistribution layer film and/or build up film laminated thereto in accordance with example embodiments of the disclosure.

FIG. 28H illustrates a cross-sectional view of a substrate core for a co-packaged optics package having one or more redistribution layers formed thereon in accordance with example embodiments of the disclosure.

FIG. 28I illustrates a cross-sectional view of a substrate core for a co-packaged optics package having one or more thermal structures formed thereon in accordance with example embodiments of the disclosure.

FIG. 29 illustrates a cross-sectional view of an embodiment of a package architecture including two or more stacked substrates and one or more dies and/or die structures having one or more semiconductor lids attached to a substrate and wherein a substrate may include an embedded die structure having semiconductor dies attached to two sides of a thermally conductive layer in accordance with example embodiments of the disclosure.

FIG. 30 illustrates a cross-sectional view of an embodiment of a co-packaged optics package architecture including two or more stacked substrates and one or more dies and/or die structures having one or more semiconductor lids attached to a substrate and wherein a substrate may include an embedded die structure having semiconductor dies attached to two sides of a thermally conductive layer in accordance with example embodiments of the disclosure.

### DETAILED DESCRIPTION

Some semiconductor packages may include one or more components embedded in a substrate. For example, in a 2.5D package, a passive or active semiconductor bridge may be embedded in a substrate to provide connections between two active components attached to a surface of the substrate. As another example, a first active semiconductor die (which may be referred to as a chip or chiplet) may be embedded in a substrate having a second active semiconductor die attached to a surface of the substrate to form a stacked configuration of active dies. Depending on the implementation details, embedding a semiconductor die in a substrate may increase the density of the package.

However, it may be difficult to control the flow of heat within and/or from a semiconductor die that is embedded in a substrate. For example, an active semiconductor die may develop hot spots that may damage the die or cause it to shut down. Removing heat from hot spots may be difficult because the heat may need to travel through the semiconductor die, the substrate, and/or any additional layers attached to the substrate. It may be especially difficult to control the flow of heat within and/or from an embedded semiconductor die that has a backside power delivery network (BSPDN) because such a die may have a relatively high power density.

Some aspects of the disclosure relate to the use of one or more thermally conductive layers to spread heat within, and/or remove heat from, one or more semiconductor dies. For example, in some embodiments, a thermally conductive layer having a relatively high thermal conductivity may be connected to a semiconductor die having a relatively low thermal conductivity. Depending on the implementation details, the thermally conductive layer may spread heat from one or more hot spots within the die, thereby reducing the temperature of one or more hot spots. Additionally, or alternatively, the thermally conductive layer may remove heat from the die and/or one or more hot spots within the die, thereby reducing the temperature of the die and/or one or more hot spots within the die. Moreover, the use of a thermally conductive layer connected to a semiconductor die may facilitate embedding the die in a substrate, for example, by improving the thermal performance of the die.

In some embodiments, semiconductor dies having relatively low thermal conductivities may be connected to two sides of a thermally conductive layer having a relatively high thermal conductivity. Depending on the implementation details, the thermally conductive layer may spread heat from one or more hot spots within one or both dies, thereby reducing the temperature of one or more hot spots. Additionally, or alternatively, the thermally conductive layer may remove heat from one or more of the dies and/or one or more hot spots within one or more of the dies, and/or may transfer heat between the dies, thereby reducing the temperature of one or more of the dies and/or one or more hot spots within one or more of the dies. Moreover, connecting semiconductor dies to two sides of a thermally conductive layer may facilitate embedding the dies in a substrate, for example, by improving the thermal performance of one or more of the dies.

Additionally, or alternatively, connecting semiconductor dies to two sides of a thermally conductive layer may reduce an area occupied by the dies. For example, connecting semiconductor dies to two sides of a thermally conductive layer may create a stacked structure that may reduce a footprint (e.g., a layout area within a package) of the dies. Additionally, or alternatively, connecting semiconductor dies to two sides of a thermally conductive layer may reduce a cost and/or thickness of the thermally conductive layer. Depending on the implementation details, the cost and/or thickness of the thermally conductive layer may be reduced without reducing one or more performance aspects of the resulting structure.

Some additional aspects of the disclosure relate to structures in which a thermally conductive layer may be located relatively close to an active layer of a semiconductor die. For example, a thinning process may be used to remove semiconductor material from a semiconductor die to form a surface that is relatively close to an active (e.g., transistor) layer of the die. A thermally conductive layer having a relatively high thermal conductivity may be connected (e.g., bonded) to the surface of the die which may have a relatively low thermal conductivity. In some embodiments, two sides of a thermally conductive layer having a relatively high thermal conductivity may be attached (e.g., bonded) to surfaces of two dies which may have relatively low thermal conductivities such that the thermally conductive layer may be located relatively close to active layers of the dies.

Depending on the implementation details, a thermally conductive layer located relatively close to an active layer of a semiconductor die may spread heat from one or more hot spots within the die, thereby reducing the temperature of one or more hot spots. Additionally, or alternatively, a thermally conductive layer located relatively close to an active layer of a semiconductor die may remove heat from the die and/or one or more hot spots within the die, thereby reducing the temperature of the die and/or one or more hot spots within the die. Moreover, a thermally conductive layer located relatively close to an active layer of a semiconductor die may facilitate embedding the die in a substrate, for example, by improving the thermal performance of the die. Additionally, or alternatively, attaching both sides of a thermally conductive layer to surfaces of two semiconductor dies that may be relatively close to active layers of the dies may create a stacked structure that may reduce a footprint (e.g., a layout area within a package) of the dies.

Some additional aspects of the disclosure relate to structures in which a first semiconductor die may be located between a second semiconductor die and a thermally conductive layer. For example, a first side of a first semiconductor die may be connected to a thermally conductive layer using any technique including one or more techniques disclosed herein. A second side of the first semiconductor die may be attached to a first side of a second semiconductor die, thereby forming a stacked structure. Depending on the implementation details, such a structure may improve the interaction of the first semiconductor die and the second semiconductor die while possibly improving thermal performance of the first and/or second dies.

For example, in some embodiments, the first semiconductor die may be implemented with a die that may provide a support function such as memory (e.g., high bandwidth memory (HBM)), cache, input and/or output (IO or I/O) such as a network or interconnect interface, energy storage (e.g., an integrated silicon capacitor ISC)), and/or the like, for the second semiconductor die which may be implemented, for example, with a general and/or specific purpose integrated circuit (e.g., an application specific integrated circuit (ASIC), a central processing unit (CPU), a graphics processing unit (GPU), a neural processing unit (NPU), tensor processing unit (TPU), data processing unit (DPU), and/or the like). Depending on the implementation details, such a structure may increase data transfer speeds between the first and second dies, reduce power consumption, support larger memory capacity, and/or the like, while possibly reducing or eliminating hot spots and/or other thermal management problems with the first and/or second dies.

One or more aspects of the disclosure may be especially useful for controlling the flow of heat within and/or from semiconductor dies having power delivery networks. For example, a semiconductor die having a power delivery network (e.g., a BSPDN) may include one or more layers forming the power delivery network located near one surface of the die, one or more layers forming a signal network near another surface of the die, and an active layer located between the power delivery network and the signal network. An embodiment in accordance with the disclosure may include a thermally conductive layer connected to the surface of the die near the signal network. Additionally, or alternatively, a thermally conductive layer may be connected to the surface of the die near the power delivery network. In some embodiments, a thermally conductive layer may be located relatively close to an active layer of a semiconductor die having a power delivery network which, depending on the implementation details, may spread heat from one or more hot spots within the die, and/or remove heat from the die and/or one or more hot spots, thereby reducing the temperature of the die and/or one or more hot spots within the die. Moreover, a structure having a thermally conductive layer located relatively close to an active layer of a semiconductor die having a power delivery network may facilitate embedding the die in a substrate, for example, in a configuration in which it may be otherwise be difficult to remove heat from the die.

In another embodiment, a first semiconductor die may include one or more layers forming a power delivery network located near one surface of the die, one or more layers forming a signal network near another surface of the die, and an active layer located between the power delivery network and the signal network. The first die may be attached to a first surface of a second semiconductor die (e.g., a die that may provide a support function such as memory to the first die). A thermally conductive layer may be attached to a second surface of the second semiconductor die and/or to a surface of the first semiconductor die. For example, the second semiconductor die may be implemented with an HBM memory stack having a first surface attached to a first surface of the first semiconductor die close to a signal network of the first die. A second surface of the HBM memory stack may be connected to a thermally conductive layer having a relatively high thermal conductivity. The first semiconductor die may be implemented with an ASIC having a power delivery network (e.g., a BSPDN) near a second surface of the ASIC. In such an embodiment, and depending on the implementation details, the thermally conductive layer may transfer heat within and/or from the first and/or second semiconductor dies (e.g., reducing hot spots), thereby increasing memory access speeds between the first and second dies, reducing power consumption by first and/or second dies, increasing bandwidth, increasing memory capacity, and/or the like.

Some additional aspects of the disclosure relate to techniques for embedding structures fabricated according to the disclosure in a substrate. For example, one or more dies attached to one or more sides of a thermally conductive layer as disclosed herein may be embedded in a substrate formed from any suitable core material including one or more organic materials, glass materials, semiconductors, and/or the like, or a combination thereof. Depending on the implementation details, these techniques may enable configurations of dies having relatively high circuitry and/or power densities to be embedded in substrates. Additionally, or alternatively, these techniques may enable relatively dense configurations of other components such as ISCs to be embedded in substrates which, depending on the implementation details, may improve the performance of power delivery networks.

Additionally, or alternatively, liquid and/or thermal channels and/or vias may be included in a substrate to improve thermal performance. Additionally, or alternatively, one or more additional dies, stacks of dies (e.g., HBM stacks), and/or other components such as ISCs may be attached to one or more sides of a substrate having one or more dies attached to one or more sides of a thermally conductive layer embedded in the substrate as disclosed herein. Additionally, or alternatively, one or more dies attached to one or more sides of a thermally conductive layer may be attached to one or more sides of a substrate having one or more dies connected to one or more sides of a thermally conductive layer embedded in the substrate as disclosed herein. Additionally, or alternatively, a substrate having one or more dies attached to one or more sides of a thermally conductive layer embedded in the substrate may be stacked with one or more additional substrates having one or more dies connected to one or more sides of a thermally conductive layer embedded therein.

This disclosure encompasses numerous aspects relating to semiconductor packaging. The aspects disclosed herein may have independent utility and may be embodied individually, and not every embodiment may utilize every aspect. Moreover, the aspects may also be embodied in various combinations, some of which may amplify some benefits of the individual aspects in a synergistic manner.

For purposes of illustration, some embodiments may be described in the context of some specific implementation details such as semiconductor die types, attachment (e.g., bonding) techniques, types of thermally conductive layers, and/or the like. However, the aspects of the disclosure are not limited to these or any other implementation details. For example, some embodiments may be described as having semiconductor dies attached to two sides of a thermally conductive layer, but some embodiments may be fabricated in the same or a similar manner with a semiconductor die attached to one side (e.g., only one side) of a thermally conductive layer.

In some embodiments, a thermally conductive layer may refer to a layer having a thermal conductivity greater than one or more semiconductor dies to which it may be attached. In some embodiments, a die may refer to a semiconductor die.

In some example embodiments described here, reference indicators having a base portion and a suffix portion may be referred to collectively and/or individually by the base portion. Multiple figures having the same numbers with different letter suffixes may be referred to collectively and/or individually by the number. For example, FIG. 3A, FIG. 3B, and/or FIG. 3C may be referred to collectively and/or individually as FIG. 3.

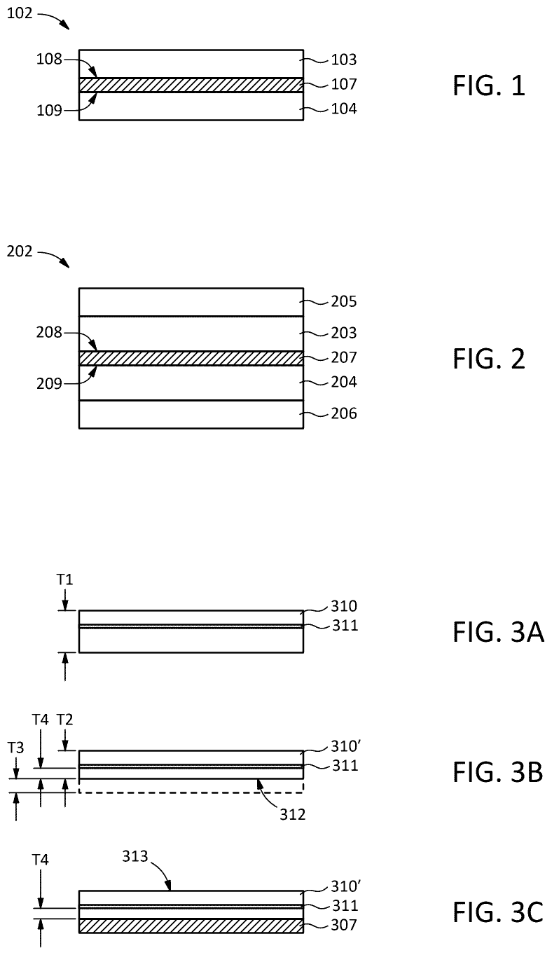

FIG. 1 illustrates a first embodiment of a semiconductor die structure in accordance with example embodiments of the disclosure. The structure 102 illustrated in FIG. 1 may include a first semiconductor die 103 having a first thermal conductivity, a second semiconductor die 104 having a second thermal conductivity, and a thermally conductive layer 107 having a third thermal conductivity. The thermally conductive layer 107 may have a first side 108 connected to the first semiconductor die 103 and a second side 109 connected to the second semiconductor die 104. The third thermal conductivity of the thermally conductive layer 107 may be greater than the first thermal conductivity of the first semiconductor die 103 and/or the second thermal conductivity of the second semiconductor die 104.

The first semiconductor die 103 and/or second semiconductor die 104 may be implemented with any type of semiconductor device such as an electronic integrated circuit (EIC), a photonic integrated circuit (PIC), and/or the like, fabricated from any type of semiconducting material or materials including silicon, gallium arsenide (GaAs), silicon carbide (SiC), silicon nitride (SiN) and/or the like, or a combination thereof. The first semiconductor die 103 and/or second semiconductor die 104 may implement any type of functionality including memory, cache, IO, energy storage (e.g., ISC), ASIC, CPU, GPU, NPU, TPU, DPU, and/or the like.

In some embodiments, the first semiconductor die 103 and/or second semiconductor die 104 may be implemented with multiple semiconductor dies such as an HBM stack. In some embodiments, the first semiconductor die 103 and/or second semiconductor die 104 may include one or more layers forming a power delivery network such as a BSPDN. In some embodiments, the first semiconductor die 103 and/or second semiconductor die 104 may have a first side bonded to the thermally conductive layer 107 and one or more layers forming a power delivery network such as a BSPDN adjacent to a second side of the die.

The thermally conductive layer 107 may be implemented with any type of material that may spread heat from one or more hot spots within one or both of dies 103 and/or 104 which, depending on the implementation details, may reduce the temperature of one or more hot spots. Additionally, or alternatively, the thermally conductive layer 107 may be implemented with any type of material that may remove heat from one or both of dies 103 and/or 104 and/or one or more hot spots within one or more of the dies 103 and/or 104, and/or may transfer heat between the dies 103 and/or 104, thereby reducing the temperature of one or more of the dies 103 and/or 104 and/or one or more hot spots within one or more of the dies 103 and/or 104.

Examples of thermally conductive materials that may spread, remove, and/or transfer heat as described herein (e.g., materials that may have a higher thermal conductivity than one or both of dies 103 and/or 104) may include single crystal diamond (SCD), polycrystalline diamond (PCD), amorphous diamond (AD), diamond-like carbon (DLC), boron arsenide, and/or the like. Other examples may include any type of material that may have a relatively wide bandgap (so it has relatively low electrical conductivity) while also having a relatively high thermal conductivity. Examples of other materials having a relatively wide bandgap and relatively high thermal conductivity may include aluminum nitride (AlN), silicon carbide (SiC), and/or the like.

The thermally conductive layer 107 may be connected to the first semiconductor die 103 and/or second semiconductor die 104 using any suitable technique such as fusion bonding (with or without applied mechanical stress), surface activated bonding, atomic diffusion bonding, plasma activated bonding, adhesive bonding, compression bonding, hydrophilic direct bonding, and/or the like. In some embodiments, fusion bonding may include any number of the following processes: flattening and/or cleaning one or both surfaces (e.g., chemically, by polishing, and/or the like), performing surface activation (e.g., using plasma activation, wet chemical solutions, and/or the like), bringing clean and/or activated surfaces into contact (with or without heat, pressure, and/or the like), annealing, and/or the like.

Although the structure 102 illustrated in FIG. 1 may include two semiconductor dies 103 and 104 connected to two sides of the thermally conductive layer 107, other embodiments may include only one semiconductor die connected to one side of the thermally conductive layer 107.

In some embodiments, thermally conductive layer 107 may be connected to first semiconductor die 103 and/or second semiconductor die 104 using an attachment technique that may be less direct than bonding, for example, using die attach film and/or the like.

In some embodiments, and depending on the implementation details, attaching (e.g., bonding) semiconductor dies to two sides of a thermally conductive layer in accordance with example embodiments of the disclosure (a process and/or apparatus that may be referred to as double-sided bonding) may enable the use of the same or similar bonding processes for bonding on both sides of the thermally conductive layer. For example, an existing or newly developed process for bonding a silicon or other semiconductor die to one side of a diamond (e.g., SCD) layer may be exploited to bond another silicon or other semiconductor die to another side of the diamond layer.

In some embodiments, and depending on the implementation details, attaching (e.g., bonding) semiconductor dies to two sides of a thermally conductive layer in accordance with example embodiments of the disclosure may exploit existing die stacking, embedding, and/or other assembly processes.

Although the embodiments described herein are not limited to any specific implementation details, diamond (e.g., SCD) may be especially beneficial in some applications. For example, the thermal conductivity of some forms of diamond (e.g., SCD) may be about 1500-2200 times greater than the thermal conductivity of glass, about 10-20 times greater than the thermal conductivity of silicon, and/or about 5-7 times greater than the thermal conductivity of copper. Thus, depending on the implementation details, diamond may improve thermal management in 2.5D and/or 3D semiconductor packages by efficiently spreading hot spots generated by active dies. Depending on the implementation details, the thickness of diamond (e.g., SCD) may be selected to achieve relatively high thermal performance and/or die and/or package size requirements. Moreover, depending on the implementation details, the thickness of diamond (e.g., SCD) may be reduced to reduce costs, possibly with little or no sacrifice in performance.

Although the embodiments described herein are not limited to the specific applications, depending on the implementation details, semiconductor packages in accordance with example embodiments of the disclosure may be especially beneficial for applications such as artificial intelligence (AI), machine learning (ML), CPUs, GPUs, NPUs, TPUs, and/or other applications that may benefit from high performance and/or high power, automotive and/or RF applications which may involve higher reliability, possibly under hash use conditions, datacenter applications which may involve relatively large packages, and/or the like.

FIG. 2 illustrates a second embodiment of a semiconductor die structure in accordance with example embodiments of the disclosure. The structure 202 illustrated in FIG. 2 may include one or more elements that may be similar to those illustrated in FIG. 1 in which similar elements may be indicated by reference numbers ending in, and/or containing, the same digits, letters, and/or the like. However, the structure 202 illustrated in FIG. 2 may include a third semiconductor die 205 attached to the first semiconductor die 203 and/or a fourth semiconductor die 206 attached to the second semiconductor die 204.

In some embodiments, the first and second semiconductor dies 203 and/or 204 may be referred to as inner dies, whereas the third and fourth semiconductor dies 205 and/or 206 may be referred to as outer dies. Although the structure 202 illustrated in FIG. 2 may be illustrated with two inner dies and two outer dies, other embodiments may have two inner dies and one outer die, one inner die and one outer die (e.g., dies attached to only one side of the thermally conductive layer 207), and/or any other configuration.

Depending on the implementation details, attaching the third semiconductor die 205 to the first semiconductor die 203 and/or attaching the fourth semiconductor die 206 to the second semiconductor die 204 may create a stacked structure that may reduce a footprint (e.g., a layout area within a package) of the dies, increase data transfer speeds between dies, improve heat flow between the dies, increase the density of the resulting structure, increase bandwidth between dies, and/or the like.

The third semiconductor die 205 and/or fourth semiconductor die 206 may be fabricated from any type of semiconducting material or materials and/or may implement any type of functionality for an EIC, a PIC, and/or the like, as described above with respect to semiconductor dies 103 and/or 104 in the structure 102 illustrated in FIG. 1 including an EIC and/or a PIC. In some embodiments, any of the first, second, third, and/or fourth semiconductor dies 203, 204, 205, and/or 206, respectively, may be implemented with multiple semiconductor dies such as an HBM stack. In some embodiments, any of the first, second, third, and/or fourth semiconductor dies 203, 204, 205, and/or 206, respectively, may include one or more layers forming a power delivery network such as a BSPDN.

Any semiconductor die may be attached to another semiconductor die (e.g., die 205 may be attached to die 203) using any type of attachment technique including hybrid bonding, micro bumps, thermo-compression bonding (TCB), die attach film, vias (e.g., through silicon vias (TSVs)), and/or the like. For example, in some embodiments, hybrid bonding techniques may be used to form bonds between metal portions of dies in a stack (e.g., metal-metal bonds) and/or between dielectric portions of dies in a stack (e.g., oxide-oxide bonds). Depending on the implementation details, hybrid bonding may improve thermal performance (e.g., reduce thermal dissipation), reduce the pitch of electrical connections between dies, increase bandwidth between dies, increase device density, and/or the like.

FIGS. 3A through 3C illustrate an embodiment of a method for fabricating a semiconductor structure having a thermally conductive layer using a thinning technique in accordance with example embodiments of the disclosure. The structure 310 illustrated in FIG. 3 may include one or more elements that may be similar to those illustrated in other figures such as FIG. 1 and/or FIG. 2 in which similar elements may be indicated by reference numbers ending in, and/or containing, the same digits, letters, and/or the like.

FIG. 3A illustrates a cross-sectional view of an embodiment of a semiconductor die having an active layer in accordance with example embodiments of the disclosure. The semiconductor die 310 may have a thickness T1 and an active layer 311 that may include one or more electronic components such as transistors, diodes, and/or the like, one or more photonic components such as lasers, modulators, detectors, amplifiers, quantum wells, and/or the like, and/or any other type of active components. The semiconductor die 310 may be fabricated from any type of semiconducting material or materials and/or may implement any type of functionality for an EIC, a PIC, and/or the like, including any of those described herein.

FIG. 3B illustrates a cross-sectional view of an embodiment of a semiconductor die with semiconductor material removed in accordance with example embodiments of the disclosure. The semiconductor die 310′ may be formed by performing a thinning operation on semiconductor die 310 illustrated in FIG. 3A to remove a portion of semiconductor material shown with dashed lines and having a thickness T3 such that thinned semiconductor die 310′ may have a resulting thickness T2 and a remaining layer of semiconductor material having a surface 312 and a thickness T4 adjacent to the active layer 311. The thickness T4 of the remaining layer of semiconductor material may be any value including zero (e.g., all semiconductor material removed from the bottom of the active layer 311) or a minimum value (e.g., just thick enough) to form a bond (e.g., a fusion bond) between the remaining layer of semiconductor material a thermally conductive layer. In an embodiment in which all or nearly all semiconductor material may be removed from active layer 311, thinned semiconductor die 310′ may be attached to a thermally conductive layer using an attachment technique such as adhesive bonding.

A thinning operation may be performed, for example, using a wafer or panel thinning operation on a wafer or panel in which die 310 may be fabricated. Examples of thinning operations may include any type of material removal process such as polishing (e.g., chemical mechanical polishing (CMP)), etching, and/or the like.

FIG. 3C illustrates a cross-sectional view of an embodiment of a structure having a thinned semiconductor die attached to a thermally conductive layer in accordance with example embodiments of the disclosure. Surface 312 (illustrated in FIG. 3B) of thinned semiconductor die 310′ may be connected to a thermally conductive layer 310 using any suitable technique such as fusion bonding and/or any of the techniques described above with respect to FIG. 1. In some embodiments, thinning semiconductor die 310′ may enable thermally conductive layer 307 to be located a distance T4 from active layer 311 which may be relatively close to (or possibly touching) active layer 311. Depending on the implementation details, this may enable the thermally conductive layer 307 to spread heat from one or more hot spots within thinned semiconductor die 310′ and/or active layer 311, thereby reducing the temperature of one or more hot spots, removing heat from die 310′ and/or one or more hot spots within die 310′, thereby reducing the temperature of die 310′ and/or one or more hot spots within the die.

In some embodiments, another semiconductor die may be attached to a surface 313 of semiconductor die 310′ in a manner similar to that in which third semiconductor die 205 in the embodiment illustrated in FIG. 2 may be attached to first semiconductor die 203.

In some embodiments, another semiconductor die having a relatively thin or nonexistent remaining layer of semiconductor material adjacent to an active layer may be connected to a second side of thermally conductive layer 307 which may result in the active layer of the second die being relatively close to the thermally conductive layer 307. Depending on the implementation details, this may create a stacked structure that may reduce a footprint (e.g., a layout area within a package) of the semiconductor dies while also improving heat flow within, into, out of, and/or between dies.

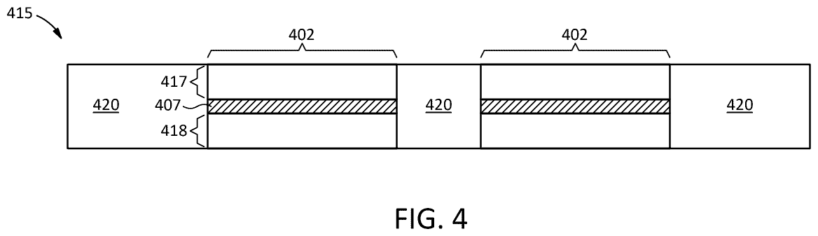

FIG. 4 illustrates a cross-sectional view of an embodiment of a substrate including one or more embedded structures having one or more semiconductor dies attached to a thermally conductive layer in accordance with example embodiments of the disclosure. The substrate 415 may include one or more embedded structures 402 that may be implemented with any of the structures having one or more semiconductor dies attached to a thermally conductive layer disclosed herein including any of those disclosed in FIG. 1, FIG. 2, and/or FIG. 3. Substrate 415 may include one or more core portions 420 that may occupy space between and/or around embedded die structures 402 to provide mechanical support for substrate 415. In some embodiments, one or more core portions 420 that may include through vias to provide electric and/or photonic connections between dies, signal layers and/or networks, power deliver layers and/or networks, and/or the like, that may be located on one or more sides of substrate 415. One or more core portions 420 may be fabricated from any suitable material including glass, semiconductor material (e.g., silicon), organic material, and/or the like, or a combination thereof.

A first die portion 417 may include one or more semiconductor dies that may be attached to thermally conductive layer 407. For example, first die portion 417 may have one die attached to a first side of thermally conductive layer 407 in a manner similar to structure 102 illustrated in FIG. 1. As another example, first die portion 417 may have a first die attached to a first side of thermally conductive layer 407 and a second die attached to the first die in a manner similar to structure 202 illustrated in FIG. 2. Additionally, or alternatively, second die portion 418 may have one die attached to a second side of thermally conductive layer 407 in a manner similar to structure 102 illustrated in FIG. 1. Additionally, or alternatively, second die portion 418 may have one die attached to a second side of thermally conductive layer 407 and a second die attached to the first die in a manner similar to structure 202 illustrated in FIG. 2.

Although not limited to any specific applications, substrate 415 may be especially beneficial for fabricating 2.5D and/or 3D semiconductor packages because, for example, one or more embedded die structures 402 having one or more thermally conductive layers 407 may provide relatively high packaging density while reducing or eliminating hot spots within one or more semiconductor dies. Moreover, using a semiconductor (e.g., silicon) and/or glass material for substrate core portions 420 may enable the fabrication of larger substrates and/or packages with higher performance due, for example, to the relative rigidness and/or higher electrical performance of semiconductor and/or glass materials.

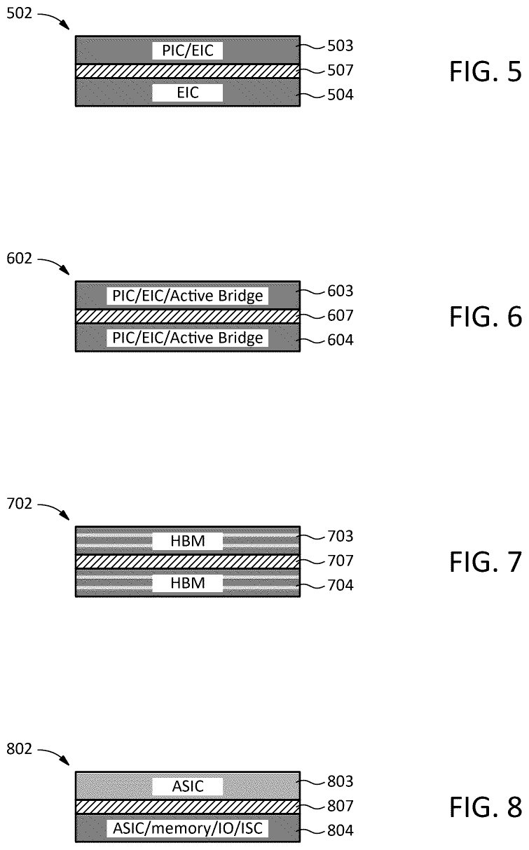

FIG. 5 illustrates a cross-sectional view of a first example embodiment of a die structure having semiconductor dies bonded to two sides of a thermally conductive layer in accordance with example embodiments of the disclosure. The structure 502 may include a first die 503 bonded to a first side of a thermally conductive layer 507, and/or a second die 504 bonded to a second side of thermally conductive layer 507. In this example, first die 503 may be implemented with a PIC, an EIC, and/or a combination thereof, but other types of dies may be used. In this example, second die 504 may be implemented with an EIC, but other types of dies may be used. Structure 502 may be used, for example, to implement structure 102 illustrated in FIG. 1 using any suitable materials, bonding techniques, and/or the like, including those described with respect to structure 102.

FIG. 6 illustrates a cross-sectional view of a second example embodiment of a die structure having semiconductor dies bonded to two sides of a thermally conductive layer in accordance with example embodiments of the disclosure. The structure 602 may include a first die 603 bonded to a first side of a thermally conductive layer 607, and/or a second die 604 bonded to a second side of thermally conductive layer 607. In this example, first die 603 may be implemented with a PIC, an active bridge, an EIC, and/or a combination thereof, but other types of dies may be used. In this example, second die 604 may also be implemented with a PIC, an active bridge, an EIC, and/or a combination thereof, but other types of dies may be used. Structure 602 may be used, for example, to implement structure 102 illustrated in FIG. 1 using any suitable materials, bonding techniques, and/or the like, including those described with respect to structure 102.

FIG. 7 illustrates a cross-sectional view of a third example embodiment of a die structure having semiconductor dies bonded to two sides of a thermally conductive layer in accordance with example embodiments of the disclosure. The structure 702 may include a first die 703 bonded to a first side of a thermally conductive layer 707, and/or a second die 704 bonded to a second side of thermally conductive layer 707. In this example, first die 703 may be implemented with one or more memory dies such as an HBM, but other types of dies may be used. In this example, second die 704 may also be implemented with one or more memory dies such as an HBM, but other types of dies may be used. Structure 702 may be used, for example, to implement structure 102 illustrated in FIG. 1 using any suitable materials, bonding techniques, and/or the like, including those described with respect to structure 102.

FIG. 8 illustrates a cross-sectional view of a first example embodiment of a die structure having semiconductor dies bonded to two sides of a thermally conductive layer in accordance with example embodiments of the disclosure. The structure 802 may include a first die 803 bonded to a first side of a thermally conductive layer 807, and/or a second die 804 bonded to a second side of thermally conductive layer 807. In this example, first die 803 may be implemented with an ASIC which, in some embodiments, may include a BSPDN, but other types of dies may be used. In this example, second die 804 may be implemented with an ASIC, one or more memory dies, an IO die, an energy storage die (e.g., an ISC), and/or a combination thereof, but other types of dies may be used. Structure 802 may be used, for example, to implement structure 102 illustrated in FIG. 1 using any suitable materials, bonding techniques, and/or the like, including those described with respect to structure 102.

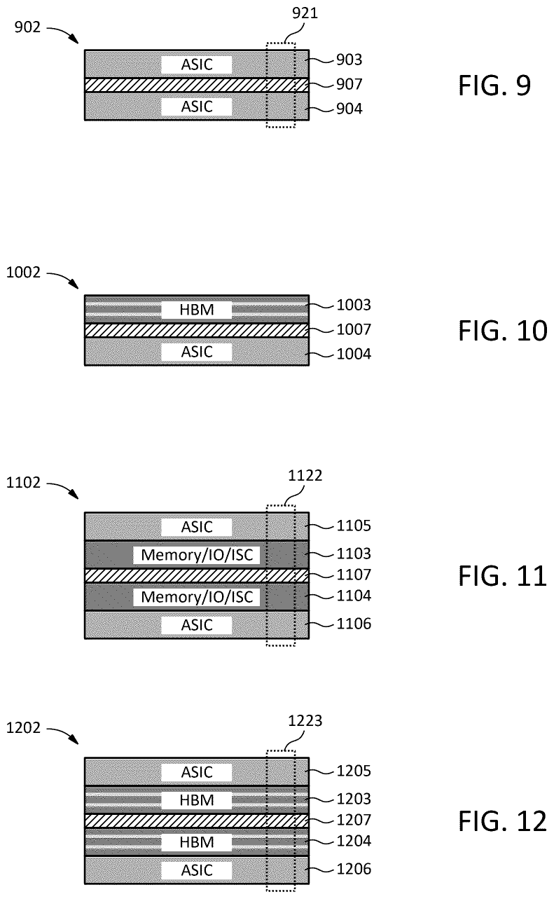

FIG. 9 illustrates a cross-sectional view of a fourth example embodiment of a die structure having semiconductor dies bonded to two sides of a thermally conductive layer in accordance with example embodiments of the disclosure. The structure 902 may include a first die 903 bonded to a first side of a thermally conductive layer 907, and/or a second die 904 bonded to a second side of thermally conductive layer 907. In this example, first die 903 may be implemented with an ASIC which, in some embodiments, may include a BSPDN, but other types of dies may be used. In this example, second die 904 may also be implemented with an ASIC which, in some embodiments, may include a BSPDN, but other types of dies may be used. Structure 902 may be used, for example, to implement structure 102 illustrated in FIG. 1 using any suitable materials, bonding techniques, and/or the like, including those described with respect to structure 102.

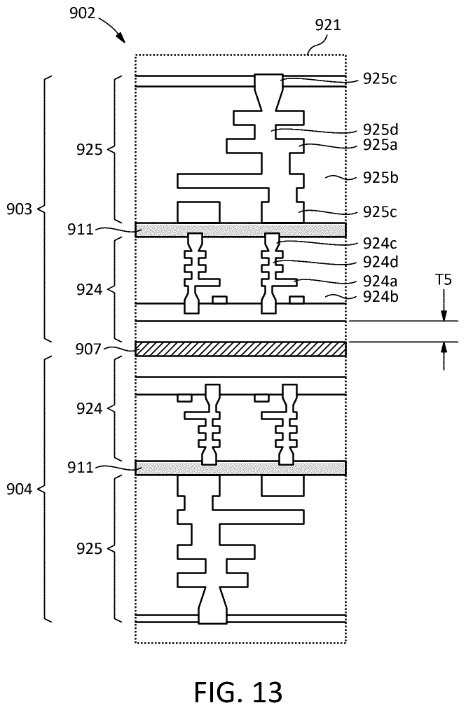

An enlarged view of an example embodiment of a portion of structure 902 indicated by dotted line box 921 is illustrated in FIG. 13.

FIG. 10 illustrates a cross-sectional view of a fifth example embodiment of a die structure having semiconductor dies bonded to two sides of a thermally conductive layer in accordance with example embodiments of the disclosure. The structure 1002 may include a first die 1003 bonded to a first side of a thermally conductive layer 1007, and/or a second die 1004 bonded to a second side of thermally conductive layer 1007. In this example, first die 1003 may be implemented with one or more memory dies such as an HBM, but other types of dies may be used. In this example, second die 1004 may be implemented with an ASIC which, in some embodiments, may include a BSPDN, but other types of dies may be used. Structure 1002 may be used, for example, to implement structure 102 illustrated in FIG. 1 using any suitable materials, bonding techniques, and/or the like, including those described with respect to structure 102.

FIG. 11 illustrates a cross-sectional view of a first example embodiment of a die structure having two stacked semiconductor dies bonded to a first side of a thermally conductive layer and two stacked semiconductor dies bonded to a second side of the thermally conductive layer in accordance with example embodiments of the disclosure. The structure 1102 may include a first die 1103 bonded to a first side of a thermally conductive layer 1107 and/or a second die 1104 bonded to a second side of thermally conductive layer 1107. Structure 1102 may also include a third die 1105 attached to first die 1103 and/or a fourth die 1106 attached to second die 1104.

In this example, first die 1103 may be implemented with one or more memory dies, IO dies, energy storage dies (e.g., ISCs), and/or a combination thereof which, in some embodiments, may be stacked, but other types of dies may be used. In this example, second die 1104 may be implemented with one or more memory dies, IO dies, energy storage dies (e.g., ISCs), and/or a combination thereof which, in some embodiments, may be stacked, but other types of dies may be used.

In this example, third die 1105 may be implemented with an ASIC which, in some embodiments, may include a BSPDN, but other types of dies may be used. In this example, fourth die 1106 may also be implemented with an ASIC which, in some embodiments, may include a BSPDN, but other types of dies may be used.

Structure 1102 may be used, for example, to implement structure 202 illustrated in FIG. 2 using any suitable materials, die attachment and/or bonding techniques, and/or the like, including those described with respect to structure 202.

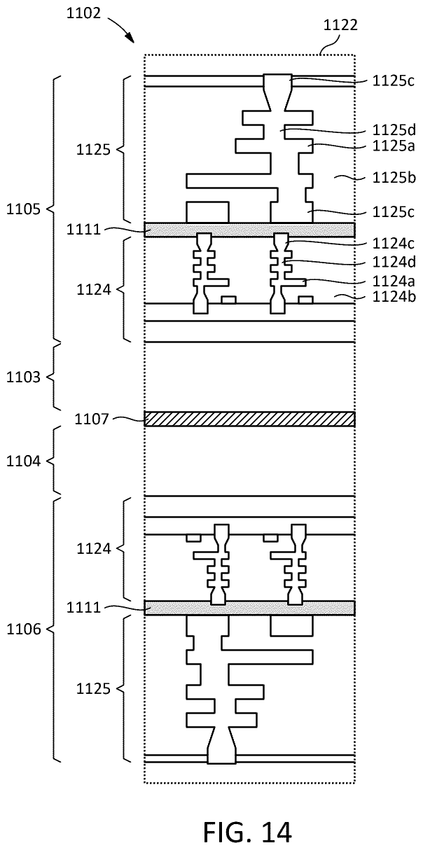

An enlarged view of an example embodiment of a portion of structure 1102 indicated by dotted line box 1122 is illustrated in FIG. 14.

FIG. 12 illustrates a cross-sectional view of a second example embodiment of a die structure having two stacked semiconductor dies bonded to a first side of a thermally conductive layer and two stacked semiconductor dies bonded to a second side of the thermally conductive layer in accordance with example embodiments of the disclosure. The structure 1202 may include a first die 1203 bonded to a first side of a thermally conductive layer 1207 and/or a second die 1204 bonded to a second side of thermally conductive layer 1207. Structure 1202 may also include a third die 1205 attached to first die 1203 and/or a fourth die 1206 attached to second die 1204.

In this example, first die 1203 may be implemented with one or more memory dies such as an HBM, but other types of dies may be used. In this example, second die 1204 may also be implemented with one or more memory dies such as an HBM, but other types of dies may be used.

In this example, third die 1205 may be implemented with an ASIC which, in some embodiments, may include a BSPDN, but other types of dies may be used. In this example, fourth die 1206 may also be implemented with an ASIC which, in some embodiments, may include a BSPDN, but other types of dies may be used.

Structure 1202 may be used, for example, to implement structure 202 illustrated in FIG. 2 using any suitable materials, die attachment and/or bonding techniques, and/or the like, including those described with respect to structure 202. Depending on the implementation details, implementing first die 1203 with an HBM die and third die 1205 with an ASIC may enable the HBM die to be closely (e.g., directly) integrated to one or more signal layers of the ASIC which may increase die-to-die connection speed, bandwidth, and/or the like, between the HBM die and the ASIC die.

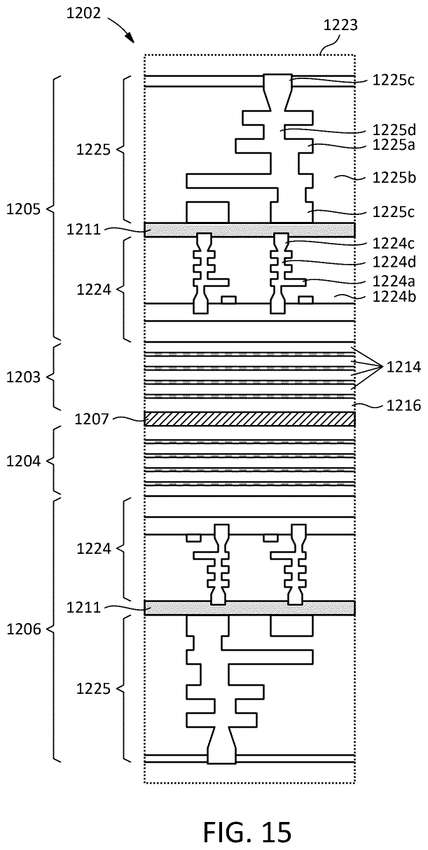

An enlarged view of an example embodiment of a portion of structure 1202 indicated by dotted line box 1223 is illustrated in FIG. 15.

FIG. 13 illustrates an enlarged cross-sectional view of a portion of the semiconductor die structure illustrated in FIG. 9. Die structure 902 may include a first die 903 and/or a second die 904 bonded to a thermally conductive layer 907. First die 903 and/or second die 904 may include a signal network 924, an active layer 911, and/or a power delivery network 925. In this example, first die 903 and/or second die 904 may be implemented with an ASIC, but other types of dies may be used. Reference numbers

[symbol]

A signal network 924 may include one or more layers of conductive traces 924a formed in a dielectric material 924b. A signal network 924 may also include one or more pads 924c and/or vias 924d to make connections with, and/or transfer signals using, the one or more layers of conductive traces 924a. For simplicity, reference numbers may only be shown for components of signal network 924 in die structure 903, but similar reference numbers apply to components of signal network 924 in die structure 904.

A power delivery network 925 may include one or more layers of conductive traces 925a formed in a dielectric material 925b that may be formed in one or more layers. A power delivery network 925 may also include one or more pads 925c and/or vias 925d to make connections with, and/or transfer power using, the one or more layers of conductive traces 925a. For simplicity, reference numbers may only be shown for components of power delivery network 925 in die structure 903, but similar reference numbers apply to components of power delivery network 925 in die structure 904.

Any or all of traces 924a and/or 925a, pads 924c and/or 925c, and/or vias 924d and/or 925d may be fabricated, for example, with any suitable conductive material(s) including metals such as copper, aluminum, and/or alloys thereof.

In this example, a power delivery network 925 may implement a BSPDN, but other types of power delivery networks may be used.

In some embodiments, first die 903 and/or second die 904 may include a portion of remaining semiconductor material having a thickness T5 resulting from a thinning operation. Depending on the implementation details, this may cause thermally conductive layer 907 to be located relatively close to an active layer 911.

FIG. 14 illustrates an enlarged cross-sectional view of a portion of the semiconductor die structure illustrated in FIG. 11. Die structure 1102 may include a first die 1103 and/or a second die 1104 bonded to a thermally conductive layer 1107. Die structure 1102 may also include a third die 1105 attached to first die 1103 and/or a fourth die 1106 attached to second die 1104.

In this example, either or both of first die 1103 and/or second die 1104 may be implemented with one or more memory dies, IO dies, energy storage dies (e.g., ISCs), and/or one or more stacks thereof, and/or a combination thereof which, in some embodiments, may be stacked, but other types of dies may be used. In this example, either or both of third die 1105 and/or fourth die 1106 may be implemented with an ASIC, but other types of dies may be used.

Either or both of third die 1105 and/or forth die 1106 may include a signal network 1124, an active layer 1111, and/or a power delivery network 1125.

A signal network 1124 may include one or more layers of conductive traces 1124a formed in a dielectric material 1124b. A signal network 1124 may also include one or more pads 1124c and/or vias 1124d to make connections with, and/or transfer signals using, the one or more layers of conductive traces 1124a. For simplicity, reference numbers may only be shown for components of signal network 924 in die structure 905, but similar reference numbers apply to components of signal network 924 in die structure 906.

A power delivery network 1125 may include one or more layers of conductive traces 1125a formed in a dielectric material 1125b that may be formed in one or more layers. A power delivery network 1125 may also include one or more pads 1125c and/or vias 1125d to make connections with, and/or transfer power using, the one or more layers of conductive traces 1125a. For simplicity, reference numbers may only be shown for components of power delivery network 925 in die structure 905, but similar reference numbers apply to components of power delivery network 925 in die structure 906.

Any or all of traces 1124a and/or 1125a, pads 1124c and/or 1125c, and/or vias 1124d and/or 1125d may be fabricated, for example, with any suitable conductive material(s) including metals such as copper, aluminum, and/or alloys thereof.

FIG. 15 illustrates an enlarged cross-sectional view of a portion of the semiconductor die structure illustrated in FIG. 12. Die structure 1202 illustrated in FIG. 15 may include one or more elements that may be similar to those illustrated in FIG. 14 and/or other figures in which similar elements may be indicated by reference numbers ending in, and/or containing, the same digits, letters, and/or the like. However, in structure 1202 illustrated in FIG. 15, either or both of first die 1203 and/or second die 1204 may be implemented with one or more memory dies configured as HBM.

In some embodiments, an HBM may be implemented with one or more stacked memory dies 1214 arranged on an interface die 1216 which may also be referred to as a base die. One or more stacked memory dies 1214 and/or interface die 1216 in an HBM may communicate using vias such as TSVs.

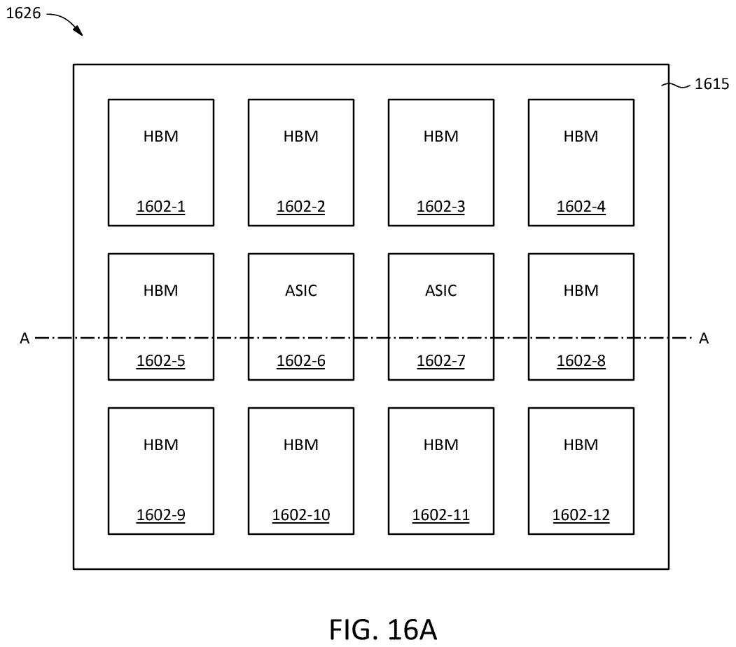

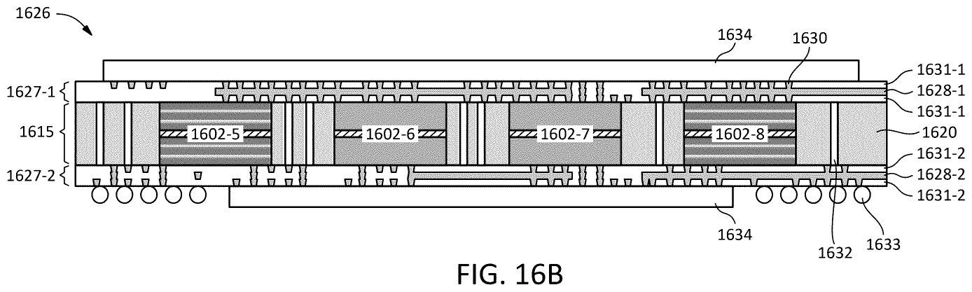

FIG. 16A illustrates a plan view of an embodiment of a package architecture including a substrate with an embedded die structure having semiconductor dies attached to two sides of a thermally conductive layer in accordance with example embodiments of the disclosure. The package architecture 1626 may include one or more die structures 1602-1, 1602-2 . . . embedded in a substrate 1615.

In this example, die structures 1602-1 . . . 1602-5 and/or 1602-8 . . . 1602-12 may be implemented with die structures having HBM stacks bonded to two sides of a thermally conductive layer similar to die structures 702 illustrated in FIG. 7, and die structures 1602-6 and/or 1602-7 may be implemented with die structures having compute and/or logic dies (e.g., ASIC dies) bonded to two sides of a thermally conductive layer similar to die structures 902 illustrated in FIG. 9, but in other embodiments, any other types and/or combinations of die structures may be used.

FIG. 16B illustrates a cross-sectional view of the embodiment of the package architecture illustrated in FIG. 16A taken through dot-dashed line A-A in accordance with example embodiments of the disclosure. Package architecture 1626 may include substrate 1615 having a first redistribution layer (RDL) and/or build up layer 1627-1 formed on a first side (e.g., top or front side) and a second RDL and/or build up layer 1627-2 formed on a second side (e.g., bottom or back side). In some embodiments, and depending on context, one or more of the RDLs 1627 may be referred to and/or characterized as being part of the substrate 1615, and/or the substrate 1615 may be referred to and/or characterized as a substrate core. For purposes of illustration, an RDL 1627 may be shown with a single layer of conductive traces 1628 and top and bottom layers of vias 1630 formed in layers of dielectric material 1631 and/or other connecting structures, but RDLs with any number of layers may be used. An RDL may also be referred to as a distribution layer.

In some embodiments, an RDL may be implemented with one or more layers of dielectric and one or more layers of conductors. For example, an RDL may include a first layer of dielectric material 1631 that may function as a substrate or base for the RDL structure. A layer 1628 of conductive traces (e.g., using metal such as copper, aluminum, and/or the like) may be formed (e.g., using one or more deposition and/or patterning techniques) on the dielectric layer 1631 to create a network of electrical connections. One or more additional layers of dielectric material 1631 and/or conductive material may be formed over the first dielectric layer 1631 and/or the first conductive layer 1628 depending on the number and/or complexity of connections to be used in the RDL. An RDL may further include one or more layers of vias and/or other connecting structures that may connect conductive traces on one layer with conductive traces on another layer and/or with one or more pads or other structures and/or devices such as dies, modules, and/or the like, connected to an RDL.

Substrate 1615 may include core portions 1620 located between and/or around die structures 1602 and fabricated from any suitable material including glass, semiconductor material (e.g., silicon), organic material, and/or the like, or a combination thereof. Substrate 1615 may include one or more vias (e.g., through silicon vias (TSVs), through glass vias (TGVs), through organic vias (TOVs), and/or the like) 1632 to connect first RDL 1627-1 and second RDL 1627-2.

One or more die structures 1602 embedded in substrate 1615 may be electrically connected to one or more other die structures 1602 and/or components embedded in substrate 1615 through first RDL 1627-1, second RDL 1627-2, and/or vias 1632 fabricated in substrate core sections 1620.

In some embodiments, package architecture 1626 may include one or more connections (e.g., solder connections such as solder balls) 1633 attached to connect first RDL 1627-1 and/or second RDL 1627-2 to enable package architecture 1626 to be connected to a packaging substrate, interposer, circuit board, or other component.

In some embodiments, package architecture 1626 may include one or more thermal structures 1634 to facilitate thermal dissipation at the top and/or bottom sides of the package architecture 1626. For example, in some embodiments, one or more thermal structures 1634 may be implemented with one or more thermally conductive lids (e.g., copper, aluminum, and/or the like) and/or liquid cooling lids 1634 that may be attached to first RDL 1627-1 and/or second RDL 1627-2. Additionally, or alternatively, one or more thermal vias and/or cooling channels (e.g., liquid cooling channels, microchannels, and/or the like) may be embedded in substrate 1615 to provide thermal dissipation at the bottom side of package architecture 1626.

Depending on the implementation details, package architecture 1626 may enable compute, logic, and/or other functionality in one or more ASICs in die structures 1602-6 and/or 1602-7 to access a relatively large amount of memory in HBM die structures 1602-1 . . . 1602-5 and/or 1602-8 . . . 1602-12 at a relatively high bandwidth. Additionally, or alternatively, depending on the implementation details, the use of one or more thermally conductive layers (e.g., SCD) in die structures 1602 may efficiently dissipate hot spots within, and/or transfer heat between, one or more dies in die structures 1602, one or more core portions 1620, one or more RDLs 1627, one or more thermal structures 1634, and/or the like. Additionally, or alternatively, locating one or more active layers in one or more dies in die structures 1602 relatively close to one or more thermally conductive layers may further improve hot spot dissipation and/or other heat transfer within and/or from die structures 1602.

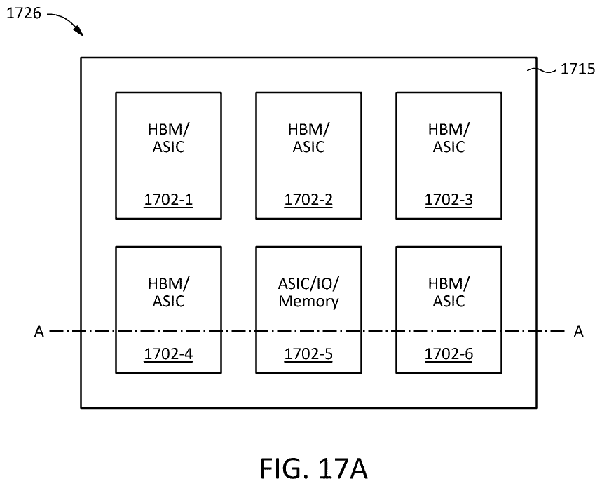

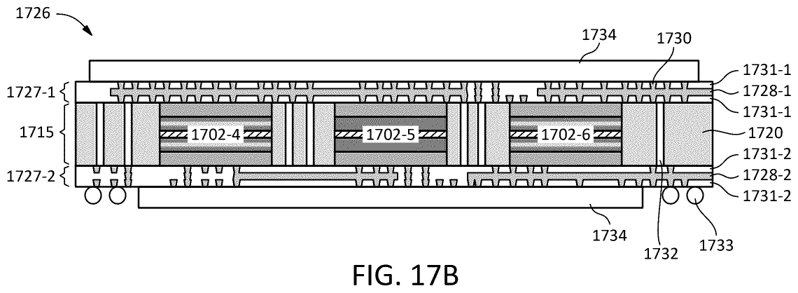

FIG. 17A illustrates a plan view of an embodiment of a package architecture including a substrate with an embedded die structure having two stacked semiconductor dies bonded to a first side of a thermally conductive layer and two stacked semiconductor dies bonded to a second side of the thermally conductive layer in accordance with example embodiments of the disclosure. The package architecture 1726 may include one or more die structures 1702-1, 1702-2 . . . embedded in a substrate 1715.

In this example, die structures 1702-1 . . . 1702-4 and/or 1702-6 may be implemented with die structures having a first compute and/or logic die (e.g., an ASIC die) stacked on a first HBM stack bonded to a first side of a thermally conductive layer and a second compute and/or logic die (e.g., an ASIC die) stacked on a second HBM stack bonded to a second side of the thermally conductive layer similar to die structure 1202 illustrated in FIG. 12, but in other embodiments, any other types and/or combinations of die structures may be used. Also in this example, die structure 1702-5 may be implemented with a die structure having a first compute and/or logic die (e.g., an ASIC die) stacked on a first memory, IO, and/or ISC die bonded to a first side of a thermally conductive layer and a second compute and/or logic die (e.g., an ASIC die) stacked on a second memory, IO, and/or ISC die bonded to a second side of the thermally conductive layer similar to die structure 1102 illustrated in FIG. 11, but in other embodiments, any other types and/or combinations of die structures may be used.

FIG. 17B illustrates a cross-sectional view of the embodiment of the package architecture illustrated in FIG. 17A taken through dot-dashed line A-A in accordance with example embodiments of the disclosure. Package architecture 1726 may include one or more elements that may be similar to those illustrated in FIG. 16 and/or other figures in which similar elements may be indicated by reference numbers ending in, and/or containing, the same digits, letters, and/or the like. For example, package architecture 1726 may include a substrate 1715 having one or more core portions 1720, one or more RDL and/or build up layers 1727-1 and/or 1727-2, one or more vias 1732, one or more connections (e.g., solder connections such as solder balls) 1733, and/or one or more thermal structures 1734.

However, in package architecture 1726, the use of die structures 1702 having two stacked dies on first and second sides of a thermally conductive layer may result in a package architecture with wider bandwidth, faster speed, and/or higher memory and/or compute and/or logic capacity, while possibly improving thermal performance (e.g., reducing or eliminating hot spots). For example, having HBM dies bonded (e.g., directly bonded using hybrid bonding) to ASIC dies which may have BSPDNs may increase the bandwidth, speed, and/or thermal performance of memory accesses of the ASIC dies. Moreover, the overall configuration of die structures 1702 illustrated in FIG. 17 may provide a compute and memory integration solution in which die structure 1702-5 may provide IO operations for die structures 1702-1 . . . 1702-4 and/or 1702-6 which may implement high performance compute operations with high-speed, high-bandwidth access to HBM memory.

For purposes of illustration, package architecture 1726 may be illustrated with die structures 1702 having two stacked dies on first and second sides of a thermally conductive layer, but in other embodiments, different numbers and/or types of die structures may be used and/or mixed in such as those illustrated with respect to FIGS. 5 through 10.

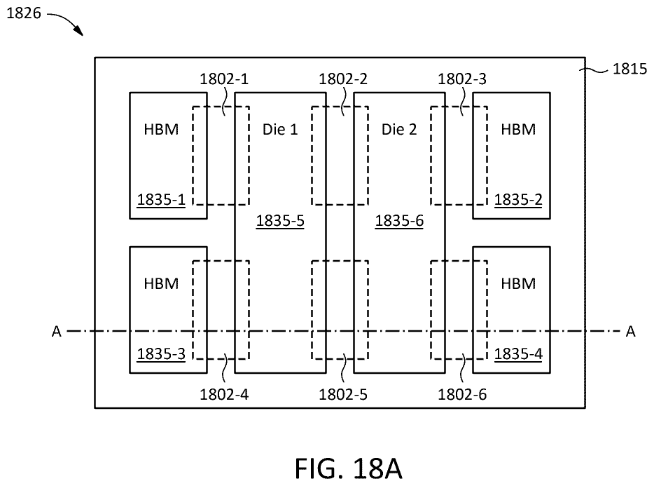

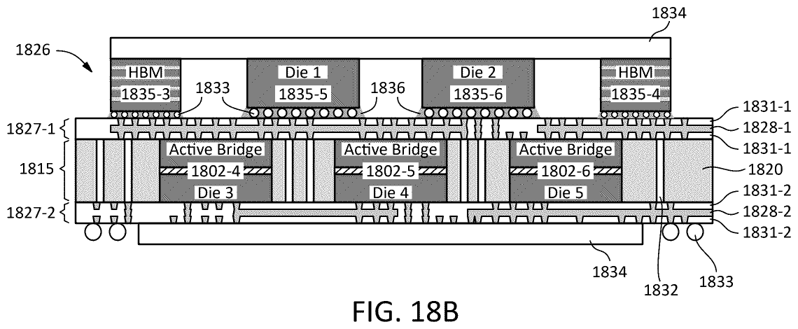

FIG. 18A illustrates a plan view of an embodiment of a package architecture including a substrate with an embedded die structure having two stacked semiconductor dies bonded to a first side of a thermally conductive layer, two stacked semiconductor dies bonded to a second side of the thermally conductive layer, and one or more dies attached to a side of the substrate in accordance with example embodiments of the disclosure. The package architecture 1826 may include one or more die structures 1802-1, 1802-2 . . . embedded in a substrate 1815. The package architecture 1826 may include one or more dies and/or die structures 1835-1, 1835-2, . . . attached to one or more sides of substrate 1815.

In this example, one or more of die structures 1802-1 . . . 1802-6 may be implemented with an active bridge bonded to one side of a thermally conductive layer similar to a top die in structure 602 illustrated in FIG. 6. In some embodiments, one or more of die structures 1802-1 . . . 1802-6 may include one or more additional dies of any type bonded to another side of the thermally conductive layer.

In this example, one or more dies and/or die structures 1835-1 . . . 1835-4 may be implemented with one or more memory dies such as an HBM stack, but in other embodiments, any other types and/or combinations of dies and/or die structures may be used. In this example, dies and/or die structures 1835-5 and/or 1835-6 may be implemented with any number and/or type of dies.

FIG. 18B illustrates a cross-sectional view of the embodiment of the package architecture illustrated in FIG. 18A taken through dot-dashed line A-A in accordance with example embodiments of the disclosure. Package architecture 1826 may include one or more elements that may be similar to those illustrated in FIG. 16 and/or other figures in which similar elements may be indicated by reference numbers ending in, and/or containing, the same digits, letters, and/or the like. For example, package architecture 1826 may include a substrate 1815 having one or more core portions 1820, one or more RDL and/or build up layers 1827-1 and/or 1827-2, one or more vias 1832, one or more connections (e.g., solder connections such as solder balls) 1833, and/or one or more thermal structures 1834 attached to one or more sides of substrate 1815, for example, attached to RDL and/or build up layer 1827-2.

However, in package architecture 1826, one or more dies and/or die structures 1835-1, 1835-2, . . . may be attached to one or more sides of substrate 1815, for example, attached to RDL and/or build up layer 1827-1. Dies and/or die structures 1835-1, 1835-2, . . . may be attached to RDL and/or build up layer 1827-1 using any suitable technique such as one or more solder connections (e.g., solder balls) 1833. In some embodiments, one or more materials such as molded underfill (MUF), epoxy molding compound (EMC), and/or the like, may be used for underfill 1836 between solder connections.

In this example, active bridges in die structures 1802 may function as connecting elements between two or more of dies and/or die structures 1835, and thus, one or more of die structures 1802 may be located at least partially under (e.g., at least partially overlapping) two or more of dies and/or die structures 1835. For example, die structure 1802-4 may be located at least partially under dies and/or die structures 1835-3 and/or 1835-5. In some embodiments, a die structure 1802 may function as both a connecting element and a compute device. Depending on the implementation details, active bridges in die structures 1802 may increase die-to-die connection speed, bandwidth, and/or the like, between dies and/or die structures 1835. In some embodiments, a passive and/or active bridge may provide one or more electrical, optical, and/or other types of connections, paths, and/or the like, between two or more dies, die structures, and/or the like. In some embodiments, a passive and/or active bridge may transmit one or more signals (e.g., electrical, optical, and/or other types of signals) from a first die to a second die and/or from the second die to the first die.

In some embodiments, package architecture 1826 may include one or more thermal structures 1834 (e.g., thermally conductive lids made from copper, aluminum, and/or the like and/or liquid cooling lids) attached to one or more of dies and/or die structures 1835 to provide thermal dissipation at the top side of package architecture 1826.

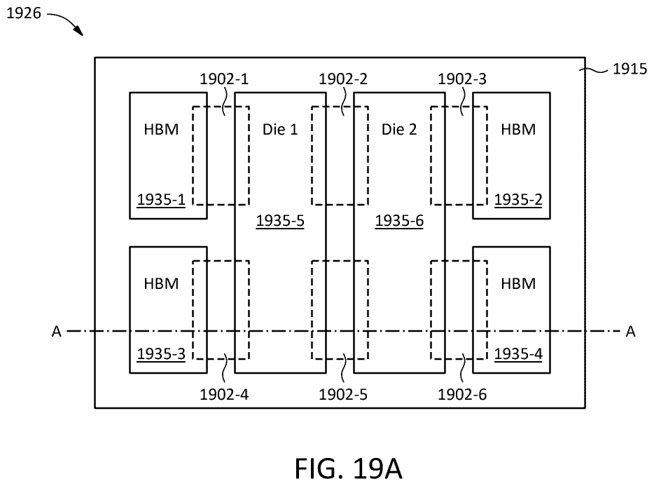

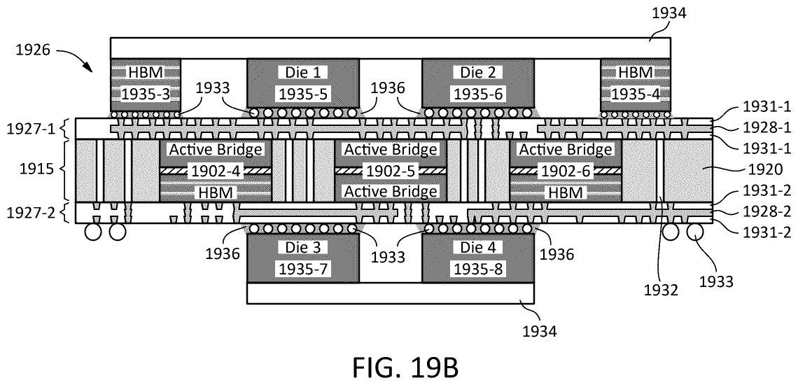

FIG. 19A illustrates a plan view of an embodiment of a package architecture including a substrate with an embedded die structure having two stacked semiconductor dies bonded to a first side of a thermally conductive layer, two stacked semiconductor dies bonded to a second side of the thermally conductive layer, one or more dies attached to a first side of the substrate, and one or more dies attached to a second side of the substrate in accordance with example embodiments of the disclosure. The package architecture 1926 may include one or more die structures 1902-1, 1902-2 . . . embedded in a substrate 1915. The package architecture 1926 may include one or more dies and/or die structures 1935-1, 1935-2, . . . attached to one or more sides of substrate 1915.

In this example, die structures 1902-1, 1902-3, 1902-4, and/or 1902-6 may be implemented with an active bridge bonded to one side of a thermally conductive layer similar to a top die in structure 602 illustrated in FIG. 6. In some embodiments, die structures 1902-1, 1902-3, 1902-4, and/or 1902-6 may include one or more additional dies of any type bonded to another side of the thermally conductive layer.

In this example, die structures 1902-2 and/or 1902-5 may be implemented with active bridges bonded to two sides of a thermally conductive layer similar to die structure 602 illustrated in FIG. 6.

In this example, dies and/or die structures 1935-1, 1935-2, 1935-3, and/or 1935-4 may be implemented with one or more memory dies such as an HBM stack, but in other embodiments, any other types and/or combinations of dies and/or die structures may be used. In this example, dies and/or die structures 1935-5 and/or 1935-6 (which may be visible in FIG. 19A) may be implemented with any number and/or type of dies. In this example, dies and/or die structures 1935-7 and/or 1935-8 (which may be located under dies and/or die structures 1935-5 and/or 1935-6, respectively, and therefor not visible in FIG. 19A) may be implemented with any number and/or type of dies.

FIG. 19B illustrates a cross-sectional view of the embodiment of the package architecture illustrated in FIG. 19A taken through dot-dashed line A-A in accordance with example embodiments of the disclosure. Package architecture 1926 may include one or more elements that may be similar to those illustrated in FIG. 17, FIG. 18, and/or other figures in which similar elements may be indicated by reference numbers ending in, and/or containing, the same digits, letters, and/or the like. For example, package architecture 1926 may include a substrate 1915 having one or more core portions 1920, one or more RDL and/or build up layers 1927-1 and/or 1927-2, one or more vias 1932, one or more connections (e.g., solder connections such as solder balls) 1933, and/or one or more thermal structures 1934 attached to dies and/or die structures 1935-1, 1935-2, 1935-5, and/or 1935-6.

However, in package architecture 1926, dies and/or die structures 1935-7 and/or 1935-8 may be attached to a bottom side of package architecture 1926, for example, attached to RDL and/or build up layer 1927-2 using one or more solder connections 1933 with underfill 1936 between solder connections.

In this example, an active bridge in the bottom of die structure 1902-5 may function as a connecting element between dies and/or die structures 1935-7 and 1935-8, and thus, die structure 1902-5 may be located at least partially above (e.g., at least partially overlapping) dies and/or die structures 1935-7 and 1935-8.

Depending on the implementation details, active bridges in die structures 1902 may increase die-to-die connection speed, bandwidth, and/or the like, between dies and/or die structures 1935.

In some embodiments, package architecture 1926 may include one or more thermal structures 1934 (e.g., thermally conductive lids made from copper, aluminum, and/or the like and/or liquid cooling lids) attached to dies and/or die structures 1935-7 and/or 1935-8 to provide thermal dissipation at the bottom side of package architecture 1926.

In this example, one or more dies bonded to a bottom of the thermally conductive layers in die structures 1902-1, 1902-3, 1902-4, and/or 1902-6 may be implemented with one or more memory dies such as an HBM stack to provide additional memory capacity to the package architecture 1926.

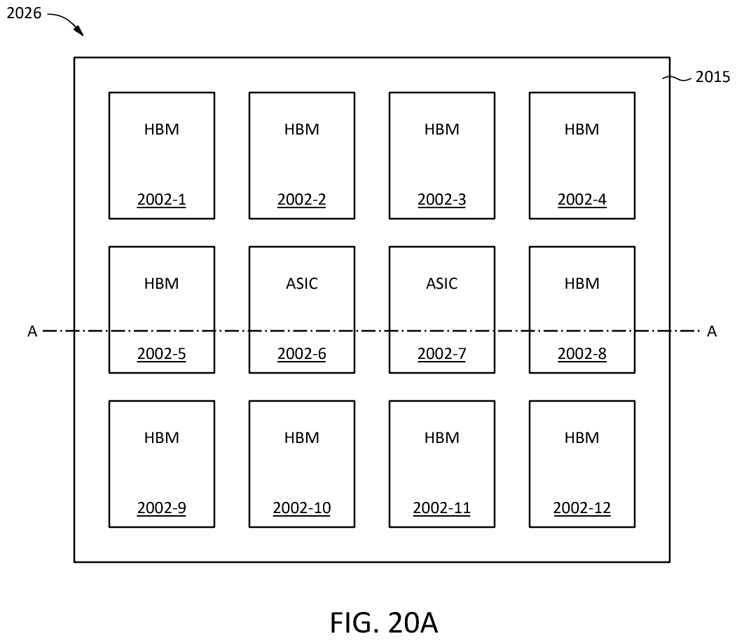

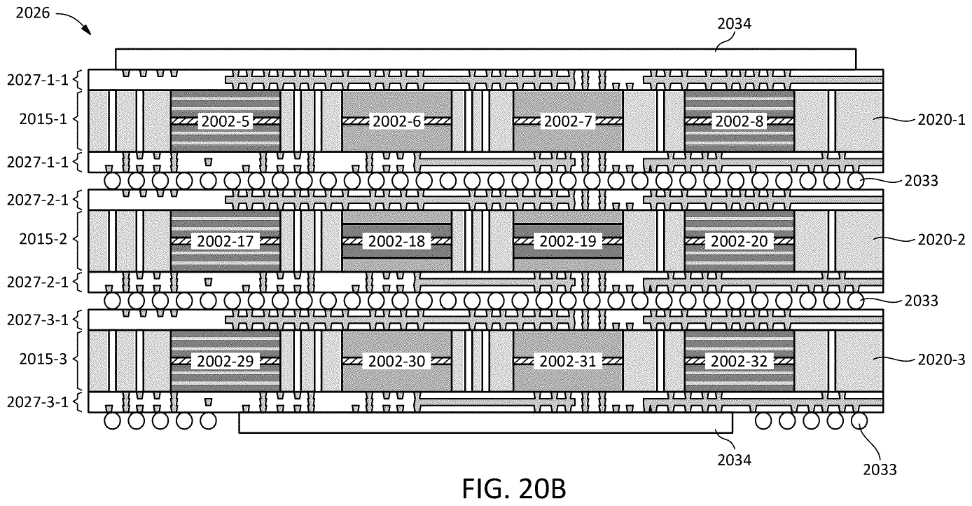

FIG. 20A illustrates a plan view of an embodiment of a package architecture including two or more stacked substrates wherein a substrate may include an embedded die structure having semiconductor dies attached to two sides of a thermally conductive layer in accordance with example embodiments of the disclosure. FIG. 20B illustrates a cross-sectional view of the embodiment of the package architecture illustrated in FIG. 20A taken through dot-dashed line A-A in accordance with example embodiments of the disclosure.

The package architecture 2026 illustrated in FIG. 20 may include two or more stacked substrates 2015-1, 2015-2, . . . , one or more of which may be implemented with a substrate similar to those illustrated with respect to FIG. 16 and/or FIG. 17 and/or a combination thereof.

In this example, three substrates 2015-1, 2015-2, and/or 2015-3 may be stacked and connected using solder connections 2033 and/or other types of electrical and/or mechanical connections. Die structures 2002 embedded in substrate 2015-1 may be designated as 2002-1 . . . 2002-12 as illustrated in FIG. 20A. Die structures 2002 embedded in substrate 2015-2 may be designated as 2002-13 . . . 2002-24 and may be located under die structures 2002-1 . . . 2002-12, respectively, and thus may not be visible in FIG. 20A. Die structures 2002 embedded in substrate 2015-3 may be designated as 2002-25 . . . 2002-36 and may be located under die structures 2002-13 . . . 2002-24, respectively, and thus may not be visible in FIG. 20A.

Package architecture 2026 may include one or more elements that may be similar to those illustrated in FIG. 16 and/or other figures in which similar elements may be indicated by reference numbers ending in, and/or containing, the same digits, letters, and/or the like. For example, one or more of substrates 2015 may include one or more core portions 2020, one or more RDL and/or build up layers 2027, one or more vias 2032, one or more connections (e.g., solder connections such as solder balls) 2033, and/or one or more thermal structures 2034.

For purposes of illustration, package architecture 2026 may be illustrated with some specific implementation details such as number of substrates 2015, number, type, and/or arrangement of die structures 2002 in each substrate 2015, and/or the like. For example, die structures 2002-1 . . . 2002-5, 2002-8 . . . 2002-12, 2002-17, 2002-20, 2002-29, and/or 2002-32 may be implemented with HBM stacks bonded to two sides of a thermally conductive layer, die structures 2002-6, 2002-7, 2002-30 and/or 2002-31 may be implemented with compute and/or logic (e.g., ASIC) dies bonded to two sides of a thermally conductive layer, and die structures 2002-18, and/or 2002-19 may be implemented with compute and/or logic (e.g., ASIC) dies stacked on memory, IO, and/or ISC dies and bonded to two sides of a thermally conductive layer. However, other embodiments may be implemented with different numbers, types, configurations, and/or the like, of substrates 2015, die structures 2022, and/or other components.

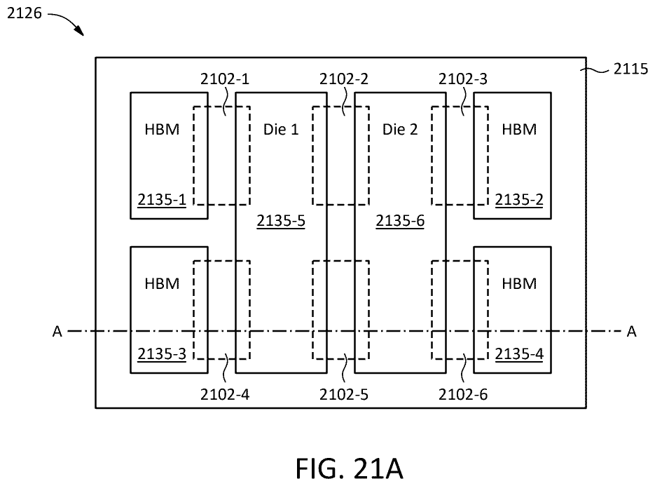

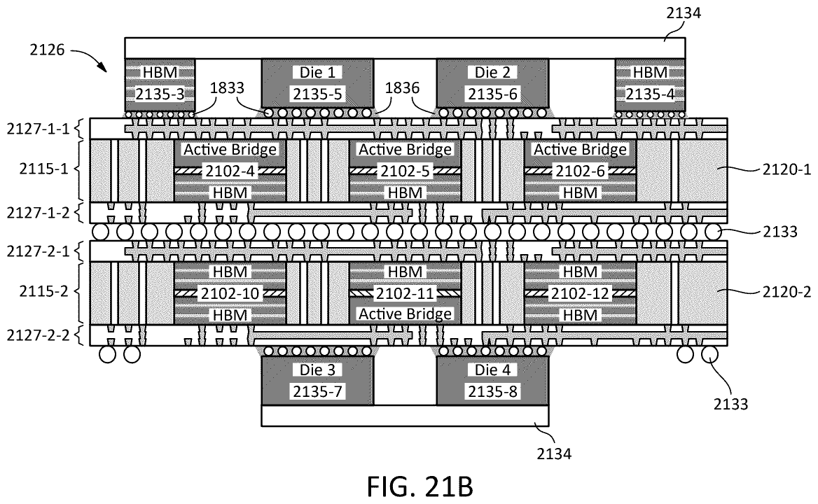

FIG. 21A illustrates a plan view of an embodiment of a package architecture including two or more stacked substrates and one or more dies and/or die structures attached to a substrate and wherein a substrate may include an embedded die structure having semiconductor dies attached to two sides of a thermally conductive layer in accordance with example embodiments of the disclosure. FIG. 21B illustrates a cross-sectional view of the embodiment of the package architecture illustrated in FIG. 21A taken through dot-dashed line A-A in accordance with example embodiments of the disclosure.

The package architecture 2126 illustrated in FIG. 21 may include two or more stacked substrates 2115-1, 2115-2, . . . , one or more of which may be implemented with a substrate similar to those illustrated with respect to FIG. 16 and/or FIG. 17 and/or a combination thereof. The package architecture 2126 illustrated in FIG. 21 may also include one or more dies and/or die structures 2135 attached to one or more sides of one or more substrates 2115 using, for example, one or more solder connections 2133 with underfill 2136 between solder connections.

In this example, two substrates 2115-1 and/or 2115-2, may be stacked and connected using solder connections 2133 and/or other types of electrical and/or mechanical connections. Dies and/or die structures 2135 attached to substrate 2115-1 may be designated as 2135-1 . . . 2135-6 as illustrated in FIG. 21A. Die structures 2102 embedded in substrate 2115-1 may be designated as 2102-1 . . . 2102-6 as illustrated in FIG. 21A. Die structures 2102 embedded in substrate 2115-2 may be designated as 2102-7 . . . 2102-12 and may be located under die structures 2102-1 . . . 2102-16, respectively, and thus may not be visible in FIG. 21A. Dies and/or die structures 2135-7 and/or 2135-8 may be attached to substrate 2115-2 and may be located under dies and/or die structures 2135-5 and/or 2135-6, respectively, and thus may not be visible in FIG. 21A.

Package architecture 2126 may include one or more elements that may be similar to those illustrated in FIG. 19 and/or other figures in which similar elements may be indicated by reference numbers ending in, and/or containing, the same digits, letters, and/or the like. For example, one or more of substrates 2115 may include one or more core portions 2120, one or more RDL and/or build up layers 2127, one or more vias 2132, one or more connections (e.g., solder connections such as solder balls) 2033, and/or one or more thermal structures 2034.

For purposes of illustration, package architecture 2126 may be illustrated with some specific implementation details such as number of substrates 2115, number, type, and/or arrangement of die structures 2102 in each substrate 2115, number, type, and/or arrangement of dies and/or die structures 2135 attached to one or more substrates 2115, and/or the like. For example, dies and/or die structures 2135-1 . . . 2135-4 may be implemented with HBM stacks, dies and/or die structures 2135-5 . . . 2135-8 may be implemented with any types of dies, die structures 2102-1 . . . 2102-6, 2102-8, and/or 2102-11 may be implemented with ASIC dies (with or without BSPDN) configured to operate as bridges bonded to one side of a thermally conductive layer and HBM stacks bonded to the other side of the thermally conductive layers, and die structures 2102-7, 2102-9, 2102-10, and/or 2102-12 may be implemented with HBM stacks bonded to two sides of a thermally conductive layer. However, other embodiments may be implemented with different numbers, types, configurations, and/or the like, of substrates 2115, dies and/or die structures 2135, die structures 2102, and/or other components.

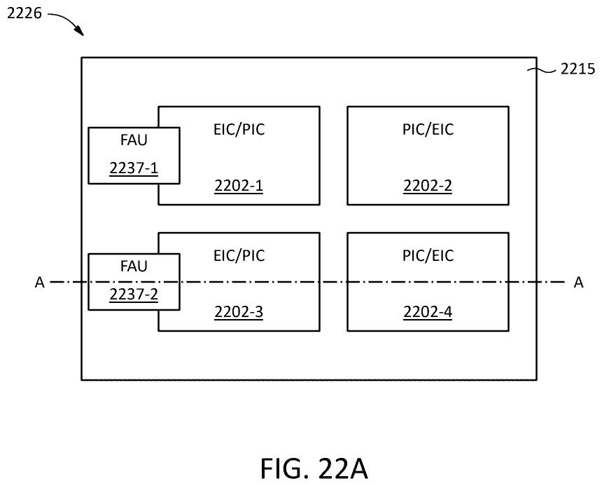

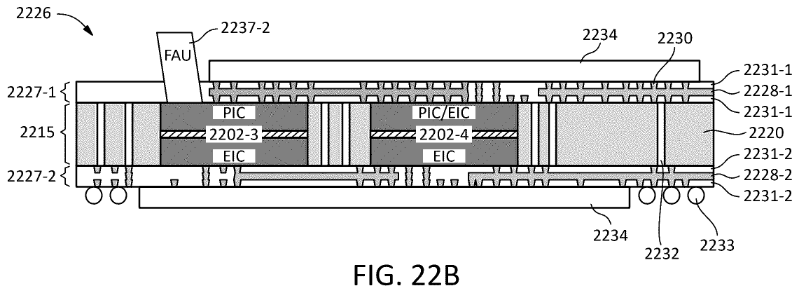

FIG. 22A illustrates a plan view of an embodiment of a co-packaged optics package architecture including a substrate having an embedded die structure with semiconductor dies attached to two sides of a thermally conductive layer in accordance with example embodiments of the disclosure. FIG. 22B illustrates a cross-sectional view of the embodiment of the package architecture illustrated in FIG. 22A taken through dot-dashed line A-A in accordance with example embodiments of the disclosure.

The package architecture 2226 illustrated in FIG. 22 may include one or more elements that may be similar to those illustrated in FIG. 16 and/or other figures in which similar elements may be indicated by reference numbers ending in, and/or containing, the same digits, letters, and/or the like. For example, substrate 2215 may include one or more core portions 2220, one or more embedded die structures 2202, one or more RDL and/or build up layers 2227, one or more vias 2232, one or more connections (e.g., solder connections such as solder balls) 2233, and/or one or more thermal structures 2234.

However, in package architecture 2226, one or more die structures 2202 may include one or more PIC dies. For example, die structures 2202-1 and/or 2202-3 may include a PIC bonded to a first side of a thermally conductive layer and/or an EIC bonded to a second side of the thermally conductive layer. As another example, die structures 2202-2 and/or 2202-4 may include a PIC and/or an EIC bonded to a first side of a thermally conductive layer and/or an EIC bonded to a second side of the thermally conductive layer.

In some embodiments, RDL lithography or other suitable technique may be used to form one or more openings in RDL and/or build up layer 2227-1 to enable a fiber array unit (FAU) 2237 or other optical coupling to be attached to one or more PICs in die structures 2202-1 and/or 2202-3.

For purposes of illustration, package architecture 2226 may be illustrated with some specific implementation details such as number, types, and/or arrangement of dies within die structures 2202, number, types, and/or arrangement of die structures 2202 within substrate 2215, and/or the like. However, other embodiments may be implemented with different numbers, types, configurations, and/or the like, of dies, die structures 2202, and/or the like.

Depending on the implementation details, attaching (e.g., directly bonding) one or more PIC dies to a thermally conductive layer in a die structure 2202 may improve the thermal performance of one or more PIC dies, FUA, and/or the like, as well as any other dies including EIC dies connected thereto. In some embodiments, die-to-die connections between PIC dies and/or EIC dies may be through vias 2232 in substrate core 2220, as well as vias and/or traces in RDL and/or build up layers 2227.

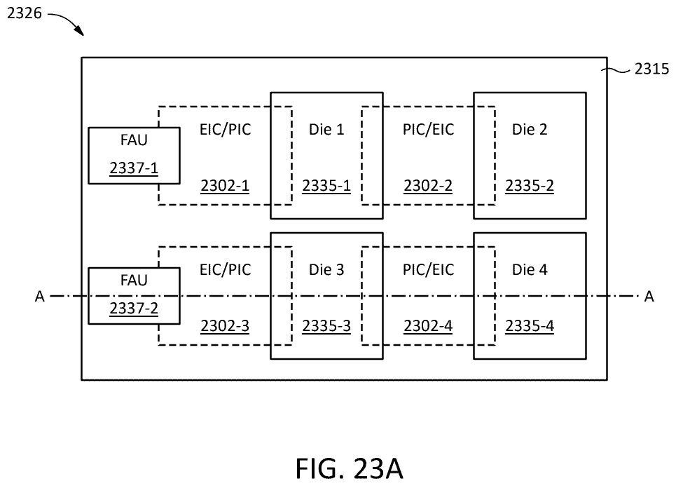

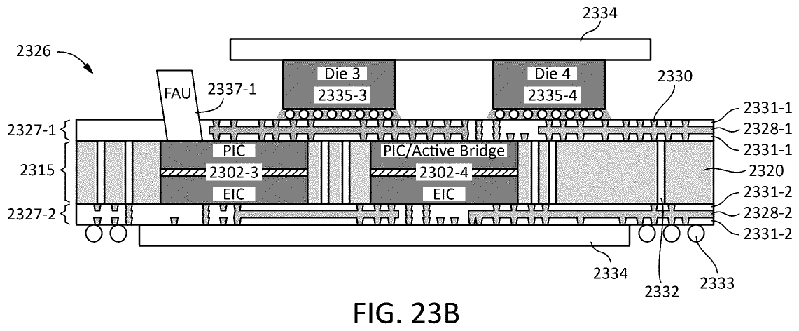

FIG. 23A illustrates a plan view of an embodiment of a co-packaged optics package architecture including a substrate having an embedded die structure with semiconductor dies attached to two sides of a thermally conductive layer and a die or die structure attached to a side of the substrate in accordance with example embodiments of the disclosure. FIG. 23B illustrates a cross-sectional view of the embodiment of the package architecture illustrated in FIG. 23A taken through dot-dashed line A-A in accordance with example embodiments of the disclosure.

The package architecture 2326 illustrated in FIG. 23 may include one or more elements that may be similar to those illustrated in FIG. 18, FIG. 22, and/or other figures in which similar elements may be indicated by reference numbers ending in, and/or containing, the same digits, letters, and/or the like. For example, substrate 2315 may include one or more core portions 2320, one or more embedded die structures 2302 with one or more PIC dies, one or more FAUs and/or other optical couplings 2337, one or more dies and/or die structures 2335 attached to a side of substrate 2315, one or more RDL and/or build up layers 2327, one or more vias 2332, one or more connections (e.g., solder connections such as solder balls) 2333, and/or one or more thermal structures 2334.

However, in package architecture 2326, one or more dies (e.g., a PIC die) in one or more of embedded die structures 2302 may operate as a bridge (e.g., an active bridge) between one or more dies and/or die structures 2335 attached to a side of substrate 2315. Depending on the implementation details, this may increase the speed of die-to-die connections to and/or from dies and/or die structures 2335 attached to one or more sides of substrate 2315.

Moreover, one or more die and/or structures 2335 may include one or more of a processing unit (e.g., CPU, GPU, NPU, TPU, and/or the like), memory (e.g., HBM), IO unit, and/or the like, to process information that may be received and/or transmitted using one or more FAUs and/or other optical couplings 2337.

For purposes of illustration, package architecture 2326 may be illustrated with some specific implementation details such as number, types, and/or arrangement of dies within die structures 2302, number, types, and/or arrangement of die structures 2302 within substrate 2315, and/or the like. However, other embodiments may be implemented with different numbers, types, configurations, and/or the like, of dies, die structures 2302, 2335, and/or the like.

Depending on the implementation details, attaching (e.g., directly bonding) one or more PIC dies to a thermally conductive layer in a die structure 2302 may improve the thermal performance of one or more PIC dies, FUA, and/or the like, as well as any other dies including EIC dies connected thereto. In some embodiments, die-to-die connections between PIC dies and/or EIC dies may be through vias 2332 in substrate core 2320, as well as vias and/or traces in RDL and/or build up layers 2327.

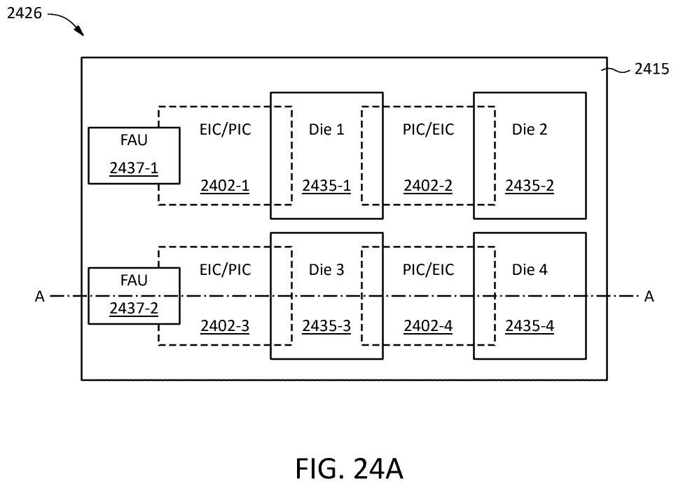

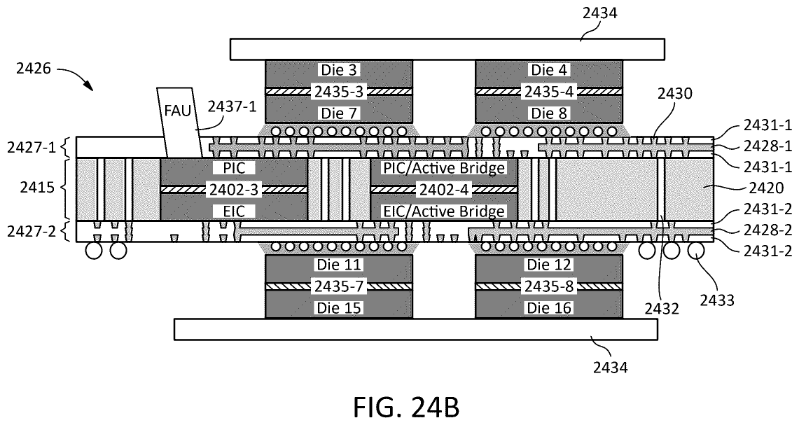

FIG. 24A illustrates a plan view of an embodiment of a co-packaged optics package architecture including a substrate having an embedded die structure with semiconductor dies attached to two sides of a thermally conductive layer and a die or die structure attached to a side of the substrate in accordance with example embodiments of the disclosure. FIG. 24B illustrates a cross-sectional view of the embodiment of the package architecture illustrated in FIG. 24A taken through dot-dashed line A-A in accordance with example embodiments of the disclosure.

The package architecture 2426 illustrated in FIG. 24 may include one or more elements that may be similar to those illustrated in FIG. 18, FIG. 22, FIG. 23, and/or other figures in which similar elements may be indicated by reference numbers ending in, and/or containing, the same digits, letters, and/or the like. For example, substrate 2415 may include one or more core portions 2420, one or more embedded die structures 2402 with one or more PIC dies, one or more FAUs and/or other optical couplings 2437, one or more dies and/or die structures 2435 attached to one or more sides of substrate 2415, one or more RDL and/or build up layers 2427, one or more vias 2432, one or more connections (e.g., solder connections such as solder balls) 2433, and/or one or more thermal structures 2434.

However, in package architecture 2426, one or more of dies and/or die structures 2435 may be implemented with a die structure having two dies bonded to two sides of a thermally conductive layer. For example, Die 1 . . . Die 4 may be bonded to a first side of a thermally conductive layer in die structures 2435-1 . . . 2435-4, respectively, and Die 5 . . . Die 8 may be bonded to a second side of the thermally conductive layers in die structures 2435-1 . . . 2435-4, respectively. Thus, Die 5 . . . Die 8 may not be visible in FIG. 24A. Similarly, Die 9 . . . Die 12 may be bonded to a first side of a thermally conductive layer in die structures 2435-5 . . . 2435-8, respectively, and Die 13 . . . Die 16 may be bonded to a second side of the thermally conductive layers in die structures 2435-5 . . . 2435-8, respectively. Moreover, die structures 2435-5 . . . 2435-8 may be located beneath die structures 2435-1 . . . 2435-4, respectively, and thus may not be visible in FIG. 24A. In some embodiments, one or more dies in die structures 2402-2 and/or 2402-4 may operate as bridges between die structures 2435-5 . . . 2435-8.

Depending on the implementation details, the use of one or more die and/or structures 2435 having dies bonded to two sides of a thermally conductive layer may increase the amount of processing units (e.g., CPU, GPU, NPU, TPU, and/or the like), memory (e.g., HBM), IO units, and/or the like, to process information that may be received and/or transmitted using one or more FAUs and/or other optical couplings 2437.

FIGS. 25A through 25H illustrate cross-sectional views of embodiments of a method for fabricating one or more die assemblies having dies bonded to a thermally conductive layer, and one or more die assemblies produced thereby, in accordance with example embodiments of the disclosure.

Referring to FIG. 25A, a first wafer (in this example an EIC wafer) 2538 having an active layer 2540 may be attached to a first carrier 2541. First wafer 2538 may have an initial thickness of T1.

Referring to FIG. 25B, first wafer 2538 may be thinned to generate a modified first wafer 2538′ having a thickness of T2 using a thinning operation that may include any type of material removal process such as polishing (e.g., CMP), etching, and/or the like. Depending on the implementation details, a thinning operation may reduce a distance T3 between active layer 2540 and a top surface of first wafer 2538. Although the principles disclosed herein are not limited to any specific implementation details, in some example embodiments, a value of T2 and/or T3 may be 10 μm or less.

In some embodiments, modified first wafer 2538′ may be tested to identify one or more known good dies (KGDs) in modified first wafer 2538′.

Referring to FIG. 25C, one or more lids of layer of thermally conductive material 2542 may be bonded to one or more KGDs in modified first wafer 2538′ using, for example, a die-on-wafer (DOW) bonding process. Although the principles disclosed herein are not limited to any specific implementation details, in some example embodiments, thermally conductive material 2542 may having a thickness between about 2 μm and 400 μm. In an embodiment in which thermally conductive material 2542 may be implemented with diamond (e.g., SCD), a lid may be referred to as a diamond lid.

Referring to FIG. 25D, a die singulation process may be performed to singulate one or more KGDs with a lid of thermally conductive material 2542 bonded thereto. Singulation may be performed by cutting, dicing, and/or any other suitable process.

Referring to FIG. 25E, singulated die assemblies 2543-1 . . . 2543-14 may be removed from first carrier 2541.

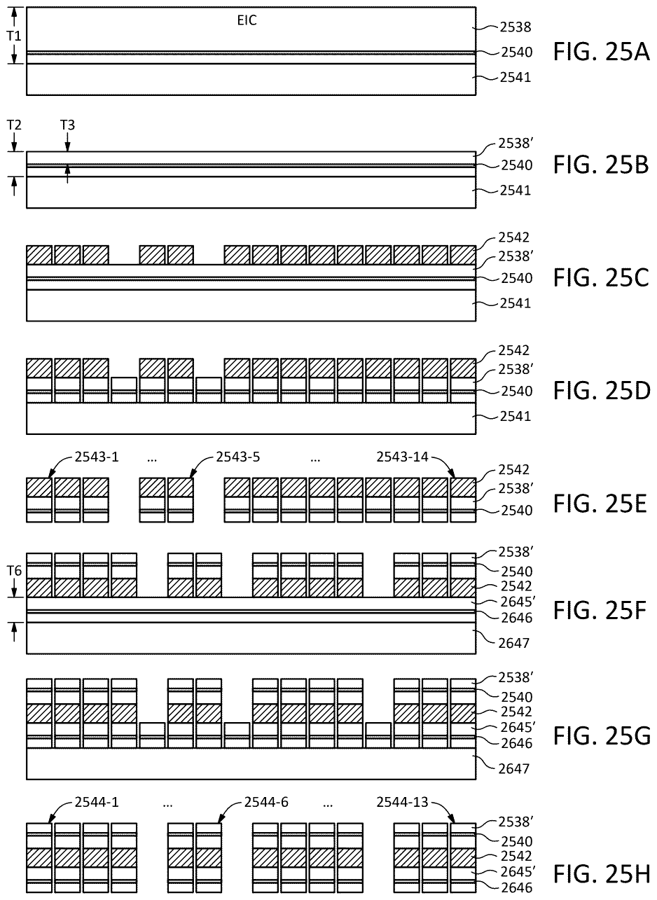

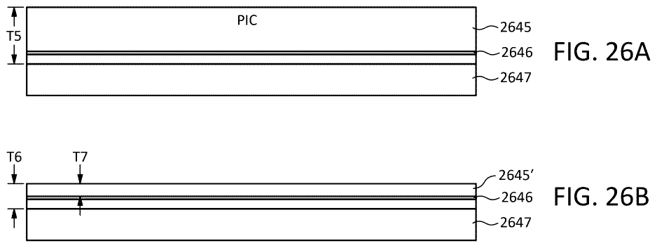

Referring to FIG. 25F, the sides of singulated die assemblies 2543-1 . . . 2543-14 having a thermally conductive material 2542 may be attached to KGDs in a modified second wafer 2645′ (in this example, a PIC wafer) attached to a second carrier 2647. Modified second wafer 2645′ may be a PIC wafer having a thickness T6 and may be fabricated, for example, using a method such as that illustrated in FIG. 26. Singulated die assemblies 2543-1 . . . 2543-14 may be bonded, for example, using a DOW bonding process.

Referring to FIG. 25G, a die singulation process may be performed to singulate one or more KGDs in modified second wafer 2645′ with a lid of thermally conductive material 2542 bonded to both KGDs in modified second wafer 2645′ and KGDs from modified first wafer 2538′. Singulation may be performed by cutting, dicing, and/or any other suitable process.

Referring to 25H, one or more die assemblies 2544-1 . . . 2544-13 with a lid of thermally conductive material 2542 bonded to KGDs in modified second wafer 2645′ and KGDs from modified first wafer 2538′ may be removed from second carrier 2647. The resulting die assemblies 2544-1 . . . 2544-13 may be referred to as double-sided dies and/or double-sided chiplets. In embodiments implemented with a thermally conductive material 2542 formed from diamond (e.g., SCD), the resulting die assemblies 2544-1 . . . 2544-13 may be referred to as diamond bonded double-sided dies or chiplets and/or SCD bonded double-sided dies or chiplets. In this example, resulting die assemblies 2544-1 . . . 2544-13 may have an EIC die on one end and a PIC die on the other end, but any types of wafers, panels, dies, and/or the like, may be used for either end of die assemblies 2544-1 . . . 2544-13.

The method illustrated with respect to FIG. 25 may be used, for example, to fabricate any of the die assemblies disclosed herein.

In some embodiments, one or both sides of die assemblies 2544-1 . . . 2544-13 may be bonded to one or more additional dies to fabricate a die assembly having two or more stacked dies bonded to one or more sides of a thermally conductive material including any of those disclosed herein such as those illustrated FIGS. 2, 12, 14, 15, 17, and/or 20.

FIGS. 26A and 26B illustrate cross-sectional views of embodiments of a method for fabricating a thinned wafer and one or more wafer assemblies produced thereby, in accordance with example embodiments of the disclosure. The embodiments illustrated in FIG. 26 may be used, for example, to fabricate a second modified wafer on a second carrier for use with the method illustrated with respect to FIG. 25.

Referring to FIG. 26A, a wafer (in this example an EIC wafer) 2645 having an active layer 2646 may be attached to a carrier 2647. Wafer 2645 may have an initial thickness of T5.

Referring to FIG. 26B, wafer 2645 may be thinned to generate a modified wafer 2645′ having a thickness of T6 using a thinning operation that may include any type of material removal process such as polishing (e.g., CMP), etching, and/or the like. Depending on the implementation details, a thinning operation may reduce a distance T7 between active layer 2646 and a top surface of modified wafer 2645′. Although the principles disclosed herein are not limited to any specific implementation details, in some example embodiments, a value of T6 and/or T7 may be 10 μm or less.

In some embodiments, modified wafer 2645′ may be tested to identify one or more known good dies (KGDs) in modified wafer 2645′.

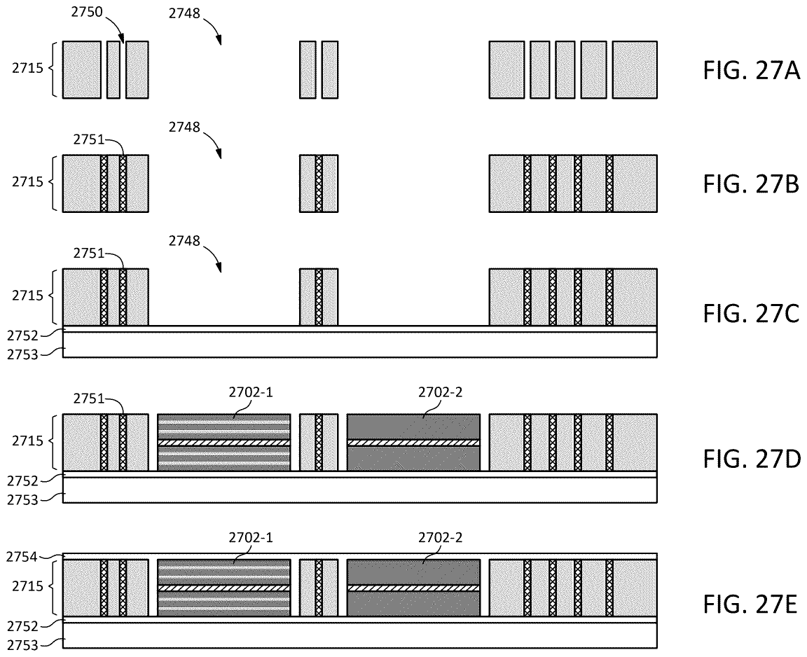

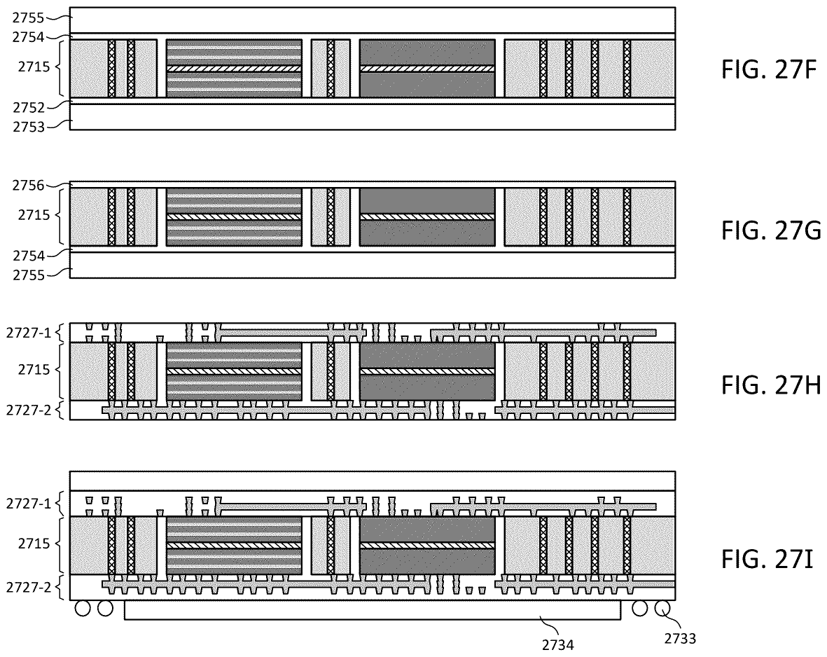

FIGS. 27A through 27I illustrate cross-sectional views of embodiments of a method for fabricating a package assembly having a substrate with one or more embedded die assemblies having dies bonded to a thermally conductive layer, and a packaging architecture produced thereby, in accordance with example embodiments of the disclosure. The method illustrated with respect to FIG. 27 may be used, for example, to fabricate any of the substrates disclosed herein, and may be performed at a wafer scale, panel scale, and/or the like.

Referring to FIG. 27A, one or more cavities 2748 for embedded die structures and/or one or more vias 2750 may be formed in a substrate core 2715. Cavities 2748 and/or vias 2750 may be formed, for example, using mechanical drilling (e.g., for organic core materials), laser processes, dry etching, wet etching (e.g., for glass and/or semiconductor cores) and/or the like.

Referring to FIG. 27B, one or more vias 2750 may be filled with conductive material 2751 such as aluminum, copper, conductive polymers, and/or the like.

Referring to FIG. 27C, a die backside film 2752 may be laminated to a first carrier 2753 and attached to a first side of substrate core 2715.

Referring to FIG. 27D, one or more die structures 2702-1, 2702-2, . . . may be embedded in one or more cavities 2748 in substrate core 2715. Die structures 2702 may be held in place in cavities 2748, for example, by die backside film 2752. For purposes of illustration, die structure 2702-1 may be illustrated as having two HBM dies attached to a thermally conductive layer in a manner similar to the embodiment illustrated in FIG. 7, and die structure 2702-2 may be illustrated as having two dies such as PIC, EIC, active bridge, memory, IO, and/or ISC attached to a thermally conductive layer in a manner similar to the embodiments illustrated in FIG. 5 and/or FIG. 6, but any numbers, types, configurations, and/or the like, of dies may be used.

Referring to FIG. 27E, an RDL dry film, build up film, and/or any other suitable material 2754 may be laminated to a second side of substrate core 2715 to form a film (e.g., a thin film) on substrate core 2715 and/or used to fill one or more gaps between one or more die structures 2702 and substrate core 2715.

Referring to FIG. 27F, a second carrier 2755 may be attached to film 2715 for handling substrate core 2715.

In the view of FIG. 27G, substrate core 2715 is flipped vertically compared to the view of FIG. 27F. Referring to FIG. 27G, first carrier 2753 and/or die backside film 2752 may be removed from substrate core 2715, and a layer 2756 of RDL dry film, build-up film, and/or the like, may be applied to the first side of substrate core 2715.

Referring to FIG. 27H, one or more vias may be formed in layers 2754 and/or 2756 of RDL dry film, build-up film, and/or the like, and filled with conductive material to form one or more connections to one or more vias 2750, die structures 2702, and/or the like. One or more additional layers of RDL dry film, build-up film, and/or the like, may be formed, and RDL lithography may be used to create vias, traces, and/or the like, which may be filled with conductive material to form RDL layers 2727-1 and/or 2727-2.

Referring to FIG. 27I, one or more connections (e.g., solder connections such as solder balls) 2733, and/or one or more thermal structures 2734 may be attached to one or more sides of substrate 2715, for example, attached to RDL and/or build up layers 2727-1 and/or 2727-2.

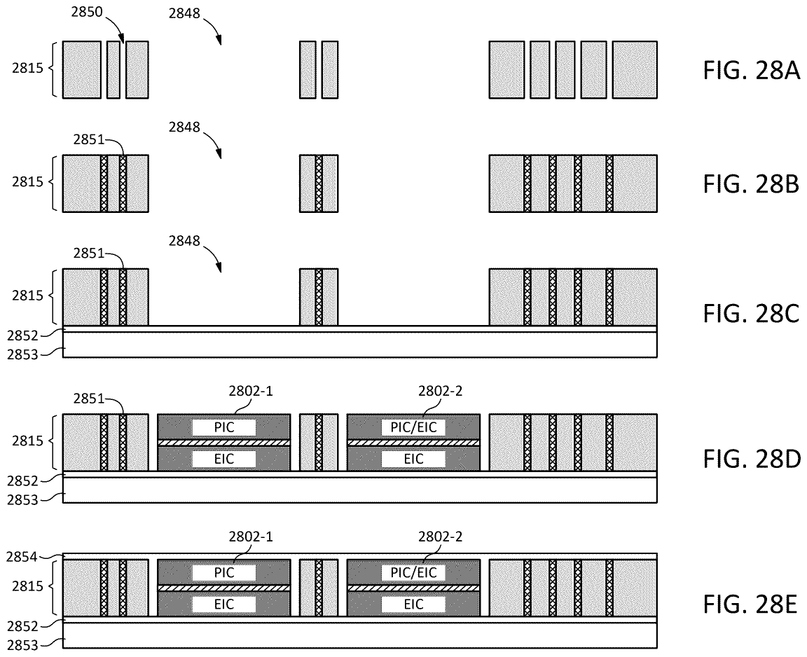

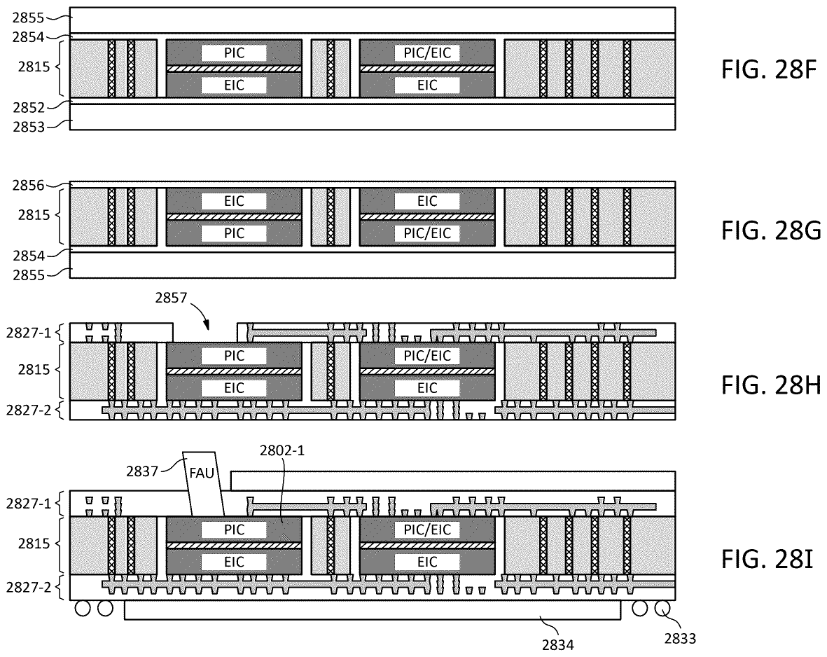

FIGS. 28A through 28I illustrate cross-sectional views of embodiments of a method for fabricating a co-packaged optics package assembly having a substrate with one or more embedded die assemblies having dies bonded to a thermally conductive layer, and a packaging architecture produced thereby, in accordance with example embodiments of the disclosure. The method illustrated with respect to FIG. 28 may be used, for example, to fabricate any of the co-packaged optics package assemblies disclosed herein, and may be performed at a wafer scale, panel scale, and/or the like.

Referring to FIGS. 28A through 28I, some of the apparatus and/or operations illustrated therein may be similar to those described with respect to the embodiments illustrated in FIGS. 27A through 27I, respectively, in which similar elements may be indicated by reference numbers ending in, and/or containing, the same digits, letters, and/or the like.

However, in the embodiments illustrated in FIGS. 28A through 28I, die structures 2802-1 and/or 2802-2 may be implemented with one or more PIC dies. For example, in this example, die structure 2802-1 may be implemented with a PIC die bonded to a first side of a thermally conductive layer and an EIC die bonded to a second side of the thermally conductive layer. Additionally, or alternatively, die structure 2802-2 may be implemented with PIC and/or EIC die bonded to a first side of a thermally conductive layer and an EIC die bonded to a second side of the thermally conductive layer. In other embodiments, any combination of number, type, and/or configurations of dies and/or die structures 2802 may be used.

Referring to FIG. 28H, an opening 2857 may be formed in RDL layers 2827-1, for example, using RDL lithography or any other suitable process.

Referring to FIG. 28I, one or more FAUs and/or other optical couplings 2837 may be attached to a PIC die in die structure 2802-1. One or more additional layers of RDL dry film, build-up film, and/or the like, may be used to fill space between one or more FAUs and/or other optical couplings 2837 and RDL layers 2827-1.

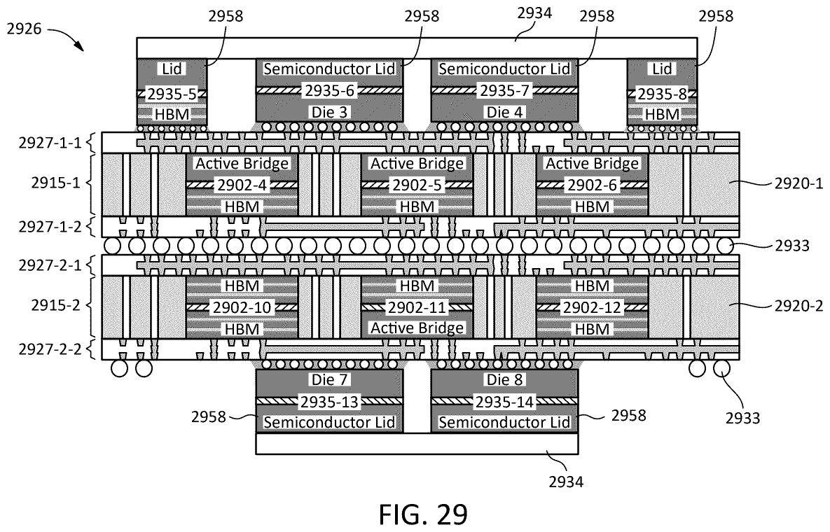

FIG. 29 illustrates a cross-sectional view of an embodiment of a package architecture including two or more stacked substrates and one or more dies and/or die structures having one or more semiconductor lids attached to a substrate and wherein a substrate may include an embedded die structure having semiconductor dies attached to two sides of a thermally conductive layer in accordance with example embodiments of the disclosure.

The embodiment illustrated in FIG. 29 may include one or more elements that may be similar to those illustrated in FIG. 21 in which similar elements may be indicated by reference numbers ending in, and/or containing, the same digits, letters, and/or the like. However, in the embodiment illustrated in FIG. 29, one or more dies and/or die structures 2935 may include one or more semiconductor (e.g., silicon) lids 2958. For example, dies and/or die structures 2935-5, 2935-6, 2935-7, 2935-8, 2935-13, and/or 2935-14, may include semiconductor lids 2958-5, 2958-6, 2958-7, 2958-8, 2958-13, and/or 2958-14, respectively. Depending on the implementation details, the use of semiconductor lids 2958 may improve the thermal performance of one or more of dies and/or die structures 2935.

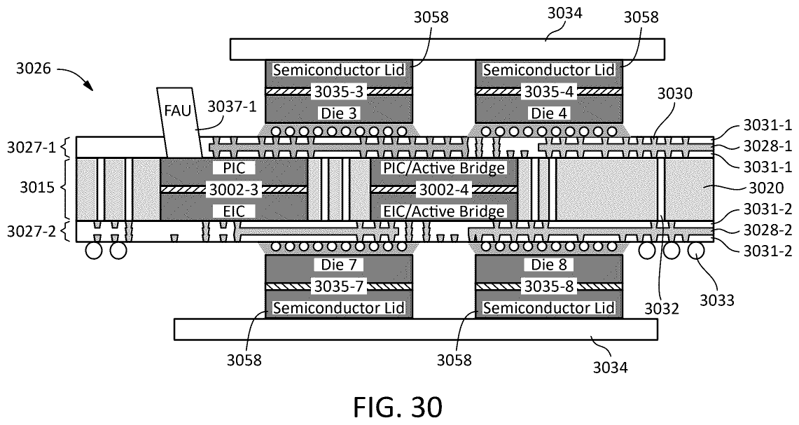

FIG. 30 illustrates a cross-sectional view of an embodiment of a co-packaged optics package architecture including two or more stacked substrates and one or more dies and/or die structures having one or more semiconductor lids attached to a substrate and wherein a substrate may include an embedded die structure having semiconductor dies attached to two sides of a thermally conductive layer in accordance with example embodiments of the disclosure.

The embodiment illustrated in FIG. 30 may include one or more elements that may be similar to those illustrated in FIG. 24 in which similar elements may be indicated by reference numbers ending in, and/or containing, the same digits, letters, and/or the like. However, in the embodiment illustrated in FIG. 30, one or more dies and/or die structures 3035 may include one or more semiconductor (e.g., silicon) lids 3058. For example, dies and/or die structures 3035-3, 3035-4, 3035-7, and/or 3035-8 may include semiconductor lids 3058-3, 3058-4, 3058-7, and/or 3058-8, respectively. Depending on the implementation details, the use of semiconductor lids 3058 may improve the thermal performance of one or more of dies and/or die structures 3035.

The operations and/or structures illustrated and described herein are example operations and/or components shown in a sequence for purposes of illustration. However, in some embodiments, some operations and/or components may be omitted and/or other operations and/or components may be included. Moreover, in some embodiments, the temporal and/or spatial order of the operations and/or components may be varied. Although some components and/or operations may be illustrated as individual components, in some embodiments, some components and/or operations shown separately may be integrated into single components and/or operations, and/or some components and/or operations shown as single components and/or operations may be implemented with multiple components and/or operations.

Some embodiments disclosed above have been described in the context of various implementation details, but the principles of this disclosure are not limited to these or any other specific details. For example, some functionality has been described as being implemented by certain components, but in other embodiments, the functionality may be distributed between different systems and components in different locations and having various interfaces. Certain embodiments have been described as having specific processes, operations, etc., but these terms also encompass embodiments in which a specific process, operation, etc. may be implemented with multiple processes, operations, etc., or in which multiple processes, operations, etc. may be integrated into a single process, step, etc. A reference to a component or element may refer to only a portion of the component or element. For example, a reference to a block may refer to the entire block or one or more subblocks. The use of terms such as “first” and “second” in this disclosure and the claims may only be for purposes of distinguishing the elements they modify and may not indicate any spatial or temporal order unless apparent otherwise from context. In some embodiments, a reference to an element may refer to at least a portion of the element, for example, “based on” may refer to “based at least in part on,” and/or the like. A reference to a first element may not imply the existence of a second element. The principles disclosed herein have independent utility and may be embodied individually, and not every embodiment may utilize every principle. However, the principles may also be embodied in various combinations, some of which may amplify the benefits of the individual principles in a synergistic manner. The various details and embodiments described above may be combined to produce additional embodiments according to the inventive principles of this patent disclosure.

In some embodiments, a portion of an element may refer to less than, or all of, the element. A first portion of an element and a second portion of the element may refer to the same portions of the element. A first portion of an element and a second portion of the element may overlap (e.g., a portion of the first portion may be the same as a portion of the second portion).

Since the inventive principles of this patent disclosure may be modified in arrangement and detail without departing from the inventive concepts, such changes and modifications are considered to fall within the scope of the following claims.

1. An apparatus comprising:
a device comprising:
a first semiconductor die having a first thermal conductivity;
a second semiconductor die having a second thermal conductivity; and
a thermally conductive layer having a third thermal conductivity, the thermally conductive layer having a first side connected to the first semiconductor die and a second side connected to the second semiconductor die;
wherein:
the third thermal conductivity is greater than the first thermal conductivity; and
the third thermal conductivity is greater than the second thermal conductivity.

2. The apparatus of claim 1, further comprising a substrate, wherein the device is at least partially embedded in the substrate.

3. The apparatus of claim 1, wherein the device further comprises a third semiconductor die attached to the first semiconductor die.

4. The apparatus of claim 1, wherein the device further comprises:
a third semiconductor die attached to the first semiconductor die; and
a fourth semiconductor attached to the second semiconductor die.

5. The apparatus of claim 1, further comprising;
a third semiconductor die; and
a fourth semiconductor die;
wherein the first semiconductor die is configured to transmit a signal from the third semiconductor die to the fourth semiconductor die.

6. The apparatus of claim 1, wherein the first semiconductor die comprises an integrated circuit.

7. The apparatus of claim 1, wherein the first semiconductor die comprises a memory die.

8. The apparatus of claim 1, wherein:
the first semiconductor die has a first side bonded to the thermally conductive layer;
the first semiconductor die comprises at least one layer configured as a power delivery network; and
the power delivery network is located adjacent to a second side of the first semiconductor die.

9. An apparatus comprising:
a substrate; and
a device at least partially embedded in the substrate, the device comprising:
a thermally conductive layer having a first thermal conductivity;
a first semiconductor die attached to a first side of the thermally conductive layer, the first semiconductor die having a second thermal conductivity; and
a second semiconductor die attached to a second side of the thermally conductive layer, the second semiconductor die having a third thermal conductivity;
wherein:
the first thermal conductivity is greater than the second thermal conductivity; and
the first thermal conductivity is greater than the third thermal conductivity.

10. The apparatus of claim 9, wherein:
the first semiconductor die is bonded to the first side of the thermally conductive layer; and
the second semiconductor die is bonded to the second side of the thermally conductive layer.

11. The apparatus of claim 9, further comprising a third semiconductor die attached to a side of the substrate.

12. The apparatus of claim 9, further comprising:
a third semiconductor die attached to a side of the substrate; and
a distribution layer attached to the substrate and configured to electrically connect the first semiconductor die to the third semiconductor die.

13. The apparatus of claim 9, further comprising:
a third semiconductor die attached to a side of the substrate; and
a fourth semiconductor die attached to the side of the substrate;
wherein the first semiconductor die is configured to transfer a signal from the third semiconductor die to the fourth semiconductor die.

14. The apparatus of claim 9, wherein the device further comprises a third semiconductor die attached to the first semiconductor die.

15. The apparatus of claim 9, wherein the device further comprises:
a third semiconductor die attached to the first semiconductor die; and
a fourth semiconductor die attached to the second semiconductor die.

16. The apparatus of claim 9, wherein the substrate is a first substrate, and the device is a first device, the apparatus further comprising a second substrate connected to the first substrate, the second substrate comprising a second device at least partially embedded in the second substrate.

17. The apparatus of claim 9, wherein the substrate is a first substrate, the device is a first device, and the thermally conductive layer is a first thermally conductive layer, wherein:
the apparatus further comprises a second substrate connected to the first substrate;
the second substrate comprises a second device at least partially embedded in the second substrate; and
the second device comprises:
a second thermally conductive layer having a fourth thermal conductivity;
a third semiconductor die having a fifth thermal conductivity attached to a first side of the second thermally conductive layer; and
a fourth semiconductor die having a sixth thermal conductivity attached to a second side of the second thermally conductive layer;
the fourth thermal conductivity is greater than the fifth thermal conductivity; and
the fourth thermal conductivity is greater than the sixth thermal conductivity.

18. A method comprising:
performing, on a semiconductor die, a thinning operation, thereby forming a modified semiconductor die; and
connecting, to the modified semiconductor die, a thermally conductive layer, thereby forming a die structure;
wherein the thermally conductive layer has a thermal conductivity that is greater than a thermal conductivity of the semiconductor die.

19. The method of claim 18, further comprising embedding, at least partially, the die structure in a substrate.

20. The method of claim 18, wherein the semiconductor die is a first semiconductor die and the modified semiconductor die is bonded to a first side of the thermally conductive layer, the method further comprising bonding, to a second side of the thermally conductive layer, a second semiconductor die.
